(19) United States
(12) Patent Application Publication
(10) Pub. No.: US 2026/0135559 A1
(43) Pub. Date: May 14, 2026

(54) SUPERCONDUCTING SWITCHES AND SIGNAL ROUTING CIRCUITRY

(71) Applicant: International Business Machines Corporation, Armonk, NY (US)

(72) Inventors: Matthew Beck, Danbury, CT (US); Ted Thorbeck, Elmsford, NY (US); Joseph Robert Suttle, Chappaqua, NY (US); Santino Carnevale, Stamford, CT (US); Joseph Finley, Rye Brook, NY (US)

(21) Appl. No.: 18/635,251

(22) Filed: Apr. 15, 2024

(51) Int. Cl. H03K 17/92; G06N 10/40; H03H 7/38

(52) U.S. Cl. CPC H03K 17/92; H03H 7/38; G06N 10/40

(57) ABSTRACT

A device comprises a superconducting switch which comprises an impedance tunable element coupled to and between a transmission line and ground. The transmission line couples a first port and a second port having matched impedances. The impedance tunable element comprises a superconducting loop comprising at least one Josephson junction, and is configured to be flux tuned into a first or second impedance state. In the first impedance state, the impedance tunable element shunts the transmission line to ground with an impedance that disrupts the impedance match between the first and second ports to suppress signal transmission between the first and second ports over the transmission line. In the second impedance state, the impedance tunable element shunts the transmission line to ground with an impedance that maintains the impedance match between the first and second ports to allow signal transmission between the first and second ports over the transmission line.

### BACKGROUND

This disclosure relates generally to quantum computing and, in particular, microwave switches and signal routing circuits for use with, e.g., superconducting quantum computing systems. A quantum computing system can be implemented using superconducting circuit quantum electrodynamics (cQED) architectures that are constructed using quantum circuit components such as, e.g., superconducting quantum bits and other types of superconducting quantum devices that are controlled using microwave control signals. In general, superconducting quantum bits (qubits) are electronic circuits which are implemented using components such as superconducting tunnel junctions (e.g., Josephson junctions), inductors, and/or capacitors, etc., and which behave as quantum mechanical anharmonic (non-linear) oscillators with quantized states, when cooled to cryogenic temperatures.

The cryogenic hardware that is utilized to implement a quantum computer with superconducting qubits requires a variety of microwave components including, e.g., qubit couplers, microwave filters, quantum limited amplifiers, Josephson parametric frequency converters and mixers, isolators, switches, and other microwave components that are implemented in qubit control and readout signal paths etc., which are controlled using various microwave control signals (e.g., radio frequency (RF) control pulses, RF pump signals, etc.). The cryogenic hardware is disposed on a base stage (e.g., millikelvin (mK) stage) of a dilution refrigerator, wherein microwave control signals generated by room temperature (e.g., 300 K) electronics are transmitted via high bandwidth lines that extend from the room temperature electronics through the dilution refrigerator to the cryogenic hardware in the base stage.

The transmission and delivery of microwave control signals in a superconducting quantum computing system is typically performed in a coarse manner where, for example, individual superconducting qubits and other quantum devices are controlled by independent stand-alone microwave drive lines. However, the number of high-bandwidth control lines for transmitting microwave control signals from the room temperature electronics to the mK stage of the dilution refrigerator scales linearly as a function of quantum device count. As a consequence, the increasing number of high-bandwidth control lines that must extend through the dilution refrigerator to support the increasing number of quantum devices to be controlled poses a limitation to quantum system scaling and integration.

### SUMMARY

Exemplary embodiments of the disclosure include superconducting switches and signal routing circuitry for transmitting and routing microwave signals in quantum computing systems.

An exemplary embodiment includes a device which comprises a superconducting switch which comprises at least one impedance tunable element coupled to and between a transmission line and a ground node. The transmission line couples a first port and a second port, which have matched impedances. The at least one impedance tunable element comprises a superconducting loop comprising at least one Josephson junction, which is configured to be flux tuned into one of a first impedance state and a second impedance state. In the first impedance state, the at least one impedance tunable element shunts the transmission line to the ground node with an impedance that disrupts the impedance match between the first port and the second port to suppress signal transmission between the first port and the second port over the transmission line. In the second impedance state, the at least one impedance tunable element shunts the transmission line to the ground node with an impedance that maintains the impedance match between the first port and the second port to allow signal transmission between the first port and the second ports over the transmission line.

Advantageously, the implementation of RF switching circuits using superconducting switches which comprise one or more impedance tunable elements (e.g., DC-SQUIDs) that shunt a transmission line to ground (e.g., ground-shunted superconducting switches that provide a tunable shunt inductance), eliminate issues such as sideband generation and low power saturation, which are associated with superconducting switches that are connected in series with transmission lines to block or allow the transmission of RF energy on the transmission lines. Indeed, ground-shunted superconducting switches do not generate sideband frequency components as a result of frequency mixing, which would cause the transfer of energy from a transmitting RF signal to generate the sideband frequency components, thereby resulting in power reduction of the transmitting RF signal. Moreover, the ground-shunted superconducting switches provide fast switching speeds (e.g., nanosecond switching speeds) and extremely low or substantially zero power dissipation, which allows the ground-shunted superconducting switches to be utilized for implementing RF switching and signal routing circuitry in a cryogenic environment (e.g., mK stage) of a dilution refrigerator. In the context of quantum computing, a single high-bandwidth wire can be used to transmit an RF signal from room temperature (e.g., 300 K) electronics to an RF switching circuit or signal routing circuit in the cryogenic environment, wherein the RF signal can be selectively routed to a target quantum device (e.g., superconducting qubit) along a given signal routing path that is selectively configured by operation of the RF switching circuit or signal routing circuit. In this regard, in a quantum computing system, the implementation of the RF switching and signal routing circuitry allows for a significant reduction in the number of high bandwidth wires for transmitting signals between the room temperature electronics and quantum devices (e.g., superconducting qubits) in a mK stage of a dilution refrigerator.

In another exemplary embodiment, as may be combined with the preceding paragraphs, the at least one impedance tunable element comprises a flux tunable inductance.

In another exemplary embodiment, as may be combined with the preceding paragraphs, the at least one impedance tunable element comprises at least one direct current superconducting quantum interference device.

In another exemplary embodiment, as may be combined with the preceding paragraphs, the at least one impedance tunable element comprises at least two direct current superconducting quantum interference devices which are connected in parallel between the transmission line and the ground node.

In another exemplary embodiment, as may be combined with the preceding paragraphs, a control line is coupled to the superconducting switch, wherein assertion of a control signal on control line causes a magnetic flux to be generated and threaded through the superconducting loop of the at least one impedance tunable element to flux bias the at least one impedance tunable element into the second impedance state, and wherein de-assertion of the control signal on the control line causes the at least one impedance tunable element to be unbiased and placed into the first impedance state.

In another exemplary embodiment, as may be combined with the preceding paragraphs, the control signal comprises a current pulse having a pulse shape that is imparted to a microwave signal that is transmitted on the transmission line to generate an amplitude modulated microwave signal having a signal envelope which corresponds to the pulse shape of the current pulse.

In another exemplary embodiment, as may be combined with the preceding paragraphs, a first control line and a second control line are coupled to the superconducting switch. The first control line is configured to apply a first control signal with a first polarity to the superconducting switch to cause a first magnetic flux to be generated and threaded through the superconducting loop of the at least one impedance tunable element. The second control line is configured to apply a second control signal with a second polarity to the superconducting switch to cause a second magnetic flux to be generated and threaded through the superconducting loop of the at least one impedance tunable element. The at least one impedance tunable element is flux tuned into the first impedance state, when the first and second polarities of the first and second control signals cause the first magnetic flux and the second magnetic flux to thread though the superconducting loop in opposite directions. The at least one impedance tunable element is flux tuned into the second impedance state, when the first and second polarities of the first and second control signals cause the first magnetic flux and the second magnetic flux to thread though the superconducting loop in a same direction.

Another exemplary embodiment includes a device which comprises a superconducting switch circuit. The superconducting switch circuit comprises switch nodes, control lines, an input port and a plurality of output ports, which have matched impedances, and a plurality of signal transmission paths. Each signal transmission path couples the input port to a respective one of the output ports. The control lines are configured to apply flux bias control signals to the switch nodes to selectively enable any one of the signal transmission paths to couple the input port to any one of the output ports, in response to the flux bias control signals applied to the switch nodes. Each switch node comprises at least one impedance tunable element coupled to and between a given signal transmission path and a ground node. The at least one impedance tunable element comprises a superconducting loop comprising at least one Josephson junction, and is configured to be flux tuned into one of a first impedance state and a second impedance state. In the first impedance state, the at least one impedance tunable element shunts the given signal transmission path to the ground node with an impedance that disrupts the impedance match between the input port and a given output port coupled to the given signal transmission path to suppress signal transmission on the given signal transmission path. In the second impedance state, the at least one impedance tunable element shunts the signal transmission path to the ground node with an impedance that maintains the impedance match between the input port and the given output port coupled to the given signal transmission path to allow signal transmission on the given signal transmission path.

Another exemplary embodiment includes a system which comprises a quantum processor, superconducting signal routing circuit, and a control system. The quantum processor comprises superconducting quantum bits. The superconducting signal routing circuit is coupled to the quantum processor. The control system which is coupled to the superconducting signal routing circuit by control lines, and is configured to control operation of the superconducting signal routing circuit. The superconducting signal routing circuit comprises: switch nodes; an input port and a plurality of output ports, which have matched impedances; and a plurality of signal transmission paths, wherein each signal transmission path couples the input port to a respective one of the output ports, each output port being coupled to a respective one of the superconducting quantum bits. The control lines of the control system are configured to apply flux bias control signals to the switch nodes to selectively enable any one of the signal transmission paths to couple the input port to any one of the output ports, in response to the flux bias control signals applied to the switch nodes. Each switch node comprises at least one impedance tunable element coupled to and between a given signal transmission path and a ground node. The at least one impedance tunable element comprises a superconducting loop comprising at least one Josephson junction, which is configured to be flux tuned into one of a first impedance state and a second impedance state. In the first impedance state, the at least one impedance tunable element shunts the given signal transmission path to the ground node with an impedance that disrupts the impedance match between the input port and a given output port coupled to the given signal transmission path to suppress signal transmission on the given signal transmission path. In the second impedance state, the at least one impedance tunable element shunts the signal transmission path to the ground node with an impedance that maintains the impedance match between the input port and the given output port coupled to the given signal transmission path to allow signal transmission on the given signal transmission path.

Other embodiments will be described in the following detailed description of exemplary embodiments, which is to be read in conjunction with the accompanying figures.

### BRIEF DESCRIPTION OF THE DRAWINGS

FIG. 1 schematically illustrates a superconducting switch circuit, according to an exemplary embodiment of the disclosure.

FIG. 2 schematically illustrates a superconducting switch circuit, according to another exemplary embodiment of the disclosure.

FIGS. 3A, 3B, and 3C depict simulated scattering parameters which show exemplary modes of operation of superconducting switch circuits, according to exemplary embodiments of the disclosure.

FIG. 4 illustrates an amplitude modulated RF signal that can be generated by controlling a superconducting switch circuit using a dynamic flux bias control signal, according to an exemplary embodiment of the disclosure.

FIGS. 5A and 5B schematically illustrate methods for flux-tuning a switch using two flux bias control signals to selectively place the switch into a high impedance state or a low impedance state, according to an exemplary embodiment of the disclosure.

FIG. 6 schematically illustrates a superconducting switch circuit, according to another exemplary embodiment of the disclosure.

FIGS. 7A, 7B, 7C, and 7D schematically illustrate exemplary modes of operation of the superconducting switch circuit of FIG. 6, according to exemplary embodiments of the disclosure.

FIG. 8 schematically illustrates readout circuitry of a quantum processing system, which can implement a superconducting switch circuit in a qubit readout signal path to provide isolation, according to an exemplary embodiment of the disclosure.

FIG. 9A schematically illustrates a superconducting signal routing circuit, according to an exemplary embodiment of the disclosure.

FIG. 9B schematically illustrates an exemplary mode of operation of the superconducting signal routing circuit of FIG. 9A, according to an exemplary embodiment of the disclosure.

FIG. 10A schematically illustrates a superconducting signal routing circuit, according to another exemplary embodiment of the disclosure.

FIG. 10B schematically illustrates an exemplary mode of operation of the superconducting signal routing circuit of FIG. 10A, according to an exemplary embodiment of the disclosure.

FIG. 11A schematically illustrates a superconducting signal routing circuit, according to another exemplary embodiment of the disclosure.

FIG. 11B schematically illustrates a superconducting signal routing circuit, according to another exemplary embodiment of the disclosure.

FIG. 12 schematically illustrates a quantum computing system which comprises superconducting signal routing circuitry, according to an exemplary embodiment of the disclosure.

FIG. 13 schematically illustrates a quantum computing system which comprises superconducting signal routing circuitry, according to another exemplary embodiment of the disclosure.

FIG. 14 schematically illustrates an exemplary architecture of a computing environment for hosting a quantum computing platform, according to an exemplary embodiment of the disclosure.

### DETAILED DESCRIPTION

Exemplary embodiments of the disclosure will now be described in further detail with regard to superconducting switches and signal routing circuitry for transmitting and routing microwave signals in quantum computing systems. It is to be understood that the various features shown in the accompanying drawings are schematic illustrations that are not drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the term “exemplary” as used herein means “serving as an example, instance, or illustration.” Any embodiment or design described herein as “exemplary” is not to be construed as preferred or advantageous over other embodiments or designs.

Further, it is to be understood that the phrase “configured to” as used in conjunction with a circuit, structure, element, component, or the like, performing one or more functions or otherwise providing some functionality, is intended to encompass embodiments wherein the circuit, structure, element, component, or the like, is implemented in hardware, software, and/or combinations thereof, and in implementations that comprise hardware, wherein the hardware may comprise superconducting quantum devices (e.g., quantum processors, quantum bits, Josephson junction devices, Josephson ring modulators, quantum-limited amplifiers (QLAs), qubit couplers, microwave switches, isolator circuits, etc.), discrete circuit elements (e.g., transistors, inverters, etc.), programmable elements (e.g., application specific integrated circuit (ASIC) chips, field-programmable gate array (FPGA) chips, etc.), processing devices (e.g., central processing units (CPUs), graphics processing units (GPUs), etc.), one or more integrated circuits, and/or combinations thereof. Thus, by way of example only, when a circuit, structure, element, component, etc., is defined to be configured to provide a specific functionality, it is intended to cover, but not be limited to, embodiments where the circuit, structure, element, component, etc., is comprised of elements, processing devices, and/or integrated circuits that enable it to perform the specific functionality when in an operational state (e.g., connected or otherwise deployed in a system, powered on, receiving an input, and/or producing an output), as well as cover embodiments when the circuit, structure, element, component, etc., is in a non-operational state (e.g., not connected nor otherwise deployed in a system, not powered on, not receiving an input, and/or not producing an output) or in a partial operational state.

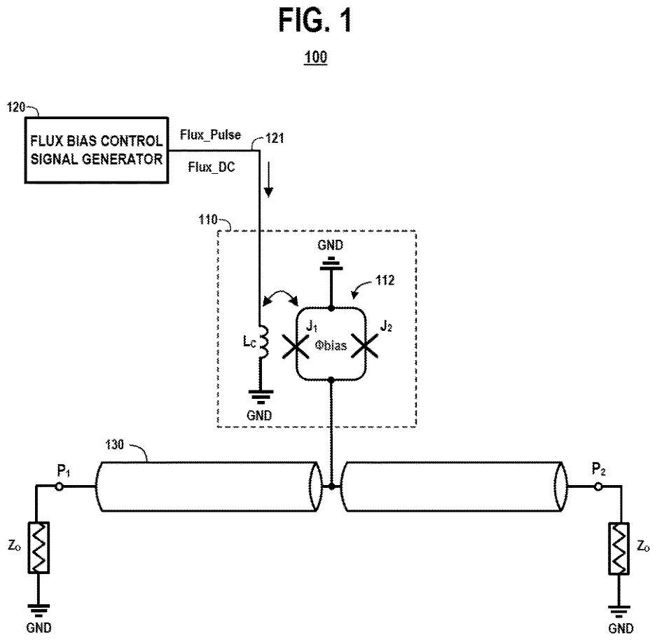

FIG. 1 schematically illustrates a superconducting switch circuit, according to an exemplary embodiment of the disclosure. In particular, FIG. 1 schematically illustrates an exemplary embodiment of a superconducting switch circuit 100 which comprises a flux-controlled switch 110 (or switch 110), and a flux bias control signal generator 120 which is configured to generate a flux bias control signal, which is applied to a control line 121, to control operation of the switch 110. In an exemplary embodiment, the switch 110 comprises a direct current superconducting quantum interference device (DC-SQUID) 112, and a coupling inductor L_{C}. The coupling inductor L_{C} is connected in series (inline) with the control line 121, and is disposed in adjacent proximity to the DC-SQUID 112. The DC-SQUID 112 comprises a superconducting loop which comprises at least two Josephson junctions including a first Josephson junction J1 and a second Josephson junction J2, which have non-linear inductances.

The DC-SQUID 112 is coupled to and between a transmission line 130 and a ground node GND. In particular, as schematically shown in FIG. 1, the DC-SQUID 112 is connected at a given point of the transmission line 130, and provides an inductive shunt to ground at the given point of the transmission line 130. The transmission line 130 comprises a first port P₁ and a second port P₂ having matched input/output impedances Z_{O} (e.g., matching nominal characteristic impedances of Z_{O}=50Ω), which correspond to the nominal characteristic impedance of the transmission line 130. While generically illustrated in FIG. 1, the transmission line 130 can be a planar transmission line such as, e.g., a coplanar waveguide (CPW) transmission line, a microstrip transmission line, a stripline transmission line, etc.

In the exemplary configuration shown in FIG. 1, the switch 110 is a ground-shunted superconducting switch which essentially operates as a single pole single throw (SPST) switch, wherein the DC-SQUID 112 is controlled to either “open” or “close” the transmission channel between the first and second ports P₁ and P₂ by modulating the effective inductance of the DC-SQUID 112 to either low inductance state (or low impedance state) or a high inductance state (or high impedance state). In particular, in some embodiments, the DC-SQUID 112 is biased into a high inductance state when the flux bias Φ_{bias} threaded through the superconducting loop is equal to, or approximately equal to, one-half the magnetic flux quantum, e.g., Φ_{bias}≈0.5 Φ₀, where the magnetic flux quantum

$${Φ}_{0} = \frac{h}{2 e}$$

(where h denotes the Planck constant and e denotes the elementary charge constant). On the other hand, the DC-SQUID 112 is biased into a low inductance state when the flux bias Φ_{bias} threaded through the superconducting loop is equal to, or approximately equal to, zero (Φ_{bias}≈0).

In some embodiments, the flux bias control signal generator 120 generates a flux bias control signal, either a DC current (denoted Flux_DC) or a current pulse (denoted Flux_Pulse) with a desired pulse envelope (e.g., square pulse, gaussian pulse, etc.) to bias the DC-SQUID 112 into a high inductance state. As a result of the flux bias control signal, the current flow through the coupling inductor L_{C} (which is disposed adjacent and in proximity to the DC-SQUID 112) is configured to generate a magnetic flux bias Φ_{bias}≈0.5 Φ₀, which threads through the superconducting loop of the DC-SQUID 112, which, in turn, modulates the inductances of the Josephson junctions J1 and J2 and places the DC-SQUID 112 into the high inductance state. On the other hand, in the absence of a flux bias control signal output from the flux bias control signal generator 120, the magnetic flux bias through the superconducting loop is equal to zero, or approximately equal to zero (Φ_{bias}≈0), and the DC-SQUID 112 is placed into a low inductance state. The flux biasing of the DC-SQUID 112 into the high inductance state or the low inductance state effectively changes the impedance matching between the first and second ports P₁ and P₂ in a way that essentially (i) allows the transmission of an RF or microwave signal between the first and second ports P₁ and P₂, or (ii) blocks the transmission of an RF or microwave signal between the first and second ports P₁ and P₂.

More specifically, when the DC-SQUID 112 is biased into a high inductance state (e.g., Φ_{bias}≈0.5 Φ₀), the DC-SQUID 112 essentially presents an RF open to ground in parallel with impedance matched first and second ports P₁ and P₂ of the transmission line 130, thereby resulting in an impedance matched system which allows an RF signal to be transmitted on the transmission line 130 between the impedance-matched first and second ports P₁ and P₂. In other words, when the DC-SQUID 112 is flux-biased at Φ_{bias}≈0.5 Φ₀, the impedance (inductance) of the DC-SQUID 112 diverges to effectively provide an infinite impedance by the DC-SQUID 112, which is in parallel with the matched impedances Z₀ of the first and second ports P₁ and P₂ of the transmission line 130. In this instance, when an RF signal (source input) is applied to, e.g., the first port P₁, the source input will effectively see only the matched output impedance Z₀ of the second port P₂, and consequently, the RF input signal will be transmitted on the transmission line 130 from the first port P₁ (input port) to the second port P₂ (output port). In this regard, when the DC-SQUID 112 is flux-biased in a high inductance state, the switch 110 is effectively in an “open” state.

On the other hand, when the DC-SQUID 112 is biased into a low inductance state (e.g., Φ_{bias}≈0), the DC-SQUID 112 essentially presents a low (unmatched, complex) impedance to ground GND, which is in parallel with impedance matched first and second ports P₁ and P₂ of the transmission line 130, thereby resulting in an inductive short to ground which blocks an RF signal from being transmitted on the transmission line 130 between the first and second ports P₁ and P₂. In other words, when the DC-SQUID 112 is flux-biased at Φ_{bias}≈0, the DC-SQUID 112 will have a relatively small inductance, which provides an inductive RF short to ground that effectively breaks the impedance match between of the first and second ports P₁ and P₂ of the transmission line 130, and forces RF energy of an input signal to be reflected back into the input port. For example, when an RF signal (source input) is applied to, e.g., the first port P₁, the source input will see not only the matched output impedance Z₀ of the second port P₂, but also the inductive RF short of the switch 110 at the point at which the switch 110 is connected to the transmission line 130, which breaks the impedance match between the first and second ports P₁ and P₂. Consequently, the energy of the RF signal input to the first port P₁ will be reflected back to the first port P₁, which blocks the transmission of the RF input signal on the transmission line 130 from the first port P₁ (input port) to the second port P₂ (output port). In this regard, when the DC-SQUID 112 is flux-biased in a low inductance state, the switch 110 is effectively in a “closed” state, providing a low impedance shunt to ground.

It is to be noted that FIG. 1 schematically illustrates an exemplary embodiment of a superconducting switch 110 which comprises an impedance tunable element (e.g., DC-SQUID 112) coupled to and between the transmission line 130 and the ground node GND. The transmission line 130 couples the first port P₁ and the second port P₂, which have matched impedances. The impedance tunable element (e.g., DC-SQUID 112) comprises a superconducting loop comprising at least one Josephson junction, and is configured to be flux tuned into a first or second impedance state. In the first impedance state, the impedance tunable element (e.g., DC-SQUID 112) shunts the transmission line 130 to ground GND with an impedance that disrupts the impedance match between the first and second ports P₁ and P₂ to suppress signal transmission between the first and second ports P₁ and P₂ over the transmission line 130. The phrase “disrupts the impedance match” denotes a state in which the impedance tunable element (e.g., the DC-SQUID 112) provides a relatively small complex impedance shunt (e.g., low inductance shunt) to ground GND (in parallel with the load) which breaks the impedance match between the first and second ports P₁ and P₂ resulting in the suppression of the RF signal energy (e.g., 30 dB or more) transmitted on the transmission line 130 from, e.g., the first port P₁ to the second port P₂.

On the other hand, in the second impedance state, the impedance tunable element (e.g., DC-SQUID 112) shunts the transmission line 130 to ground GND with an impedance that maintains the impedance match between the first and second ports P₁ and P₂ to allow signal transmission between the first and second ports P₁ and P₂ over the transmission line 130. The phrase “maintains the impedance match” denotes a state in which the impedance tunable element (e.g., the DC-SQUID 112) provides a relatively large complex impedance shunt (e.g., high inductance shunt) to ground GND (in parallel with the load) which does not break the impedance match between the first and second ports P₁ and P₂ thereby allowing unity or near unity RF power transmission over the transmission line 130 from, e.g., the first port P₁ to the second port P₂,

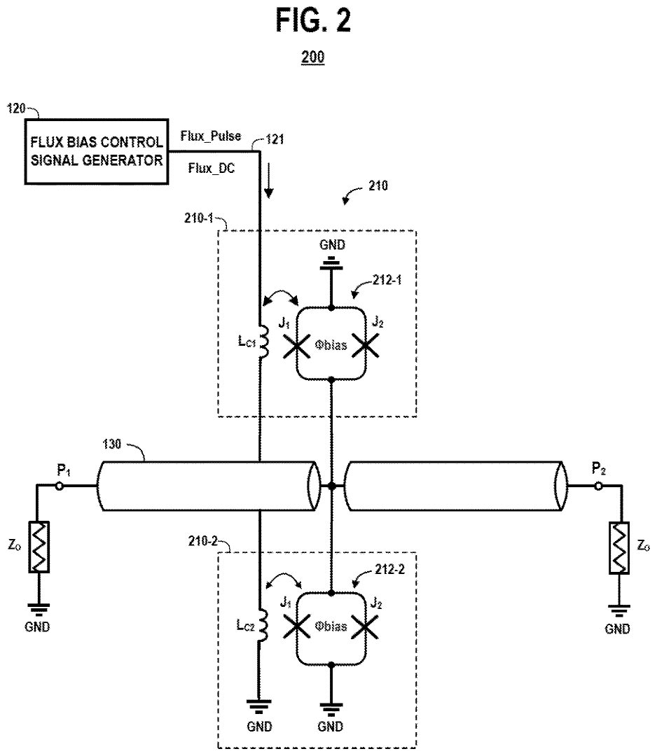

Next, FIG. 2 schematically illustrates a superconducting switch circuit, according to another exemplary embodiment of the disclosure. In particular, FIG. 2 schematically illustrates an exemplary embodiment of a superconducting switch circuit 200 which is similar to superconducting switch circuit 100 of FIG. 1, except that the superconducting switch circuit 200 comprises a switch 210 having two switches, a first switch 210-1 and a second switch 210-2, which are connected in parallel to and between a given point of the transmission line 130 and ground GND. The first switch 210-1 comprises a first DC-SQUID 212-1, and a first coupling inductor L_{C1} which is disposed in adjacent proximity to the first DC-SQUID 212-1. Similarly, the second switch 210-2 comprises a second DC-SQUID 212-2, and a second coupling inductor L_{C2} which is disposed in adjacent proximity to the second DC-SQUID 212-2. The first and second coupling inductors L_{C1} and L_{C2} are connected in series (in line) with the control line 121, such that the same control signal (e.g., Flux_Pulse or Flux_DC) is used to flux bias the first and second DC-SQUIDs 212-1 and 212-2.

It is to be noted that the first and second switches 210-1 and 210-2 operate in the same or similar manner as the switch 110 (FIG. 1) as discussed above, the details of which need not be repeated. In the exemplary configuration of FIG. 2, the switch 210 essentially comprises a plurality of DC-SQUIDs (e.g., the first and second DC-SQUIDs 212-1 and 212-2) which are coupled in parallel, providing a plurality of inductances that are coupled in parallel and shunted to ground GND. In this regard, FIG. 2 illustrates an exemplary embodiment in which the impedance tunable element comprises at least two DC-SQUIDs coupled in parallel to and between the transmission line 130 and ground GND. As explained in further detail below, the addition of two or more DC-SQUIDs in parallel and shunted to ground GND serves to increase the amount of S₂₁ (transmission) rejection as compared to the single DC-SQUID 111 of the switch 110 of FIG. 1.

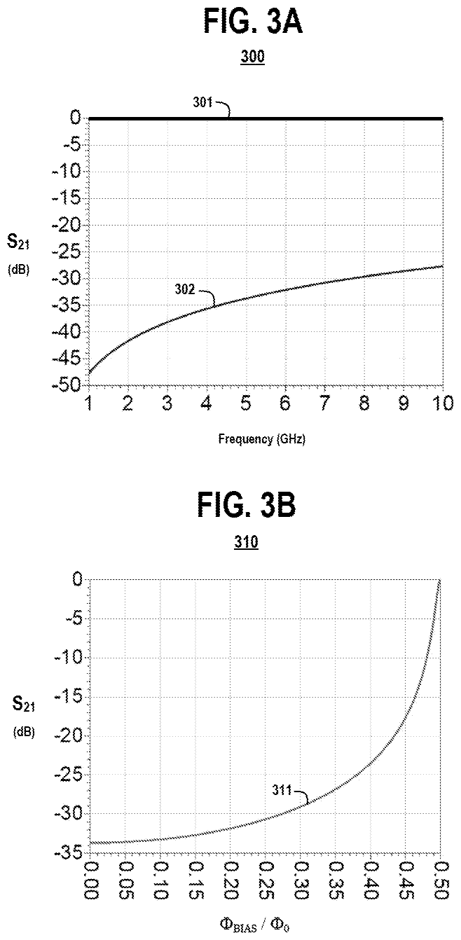

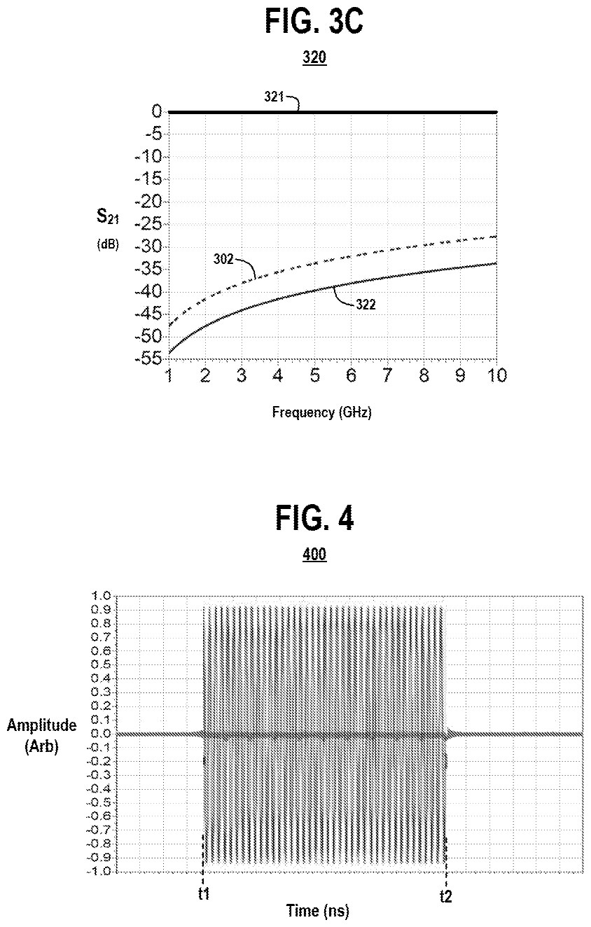

FIGS. 3A, 3B, and 3C depict simulated scattering parameters which show exemplary modes of operation of superconducting switch circuits, according to exemplary embodiments of the disclosure. For example, FIG. 3A is a graph 300 which illustrates simulated S₂₁ scattering parameters 301 and 302 showing insertion loss (S₂₁) in terms of power in dB (y-axis) as a function of frequency in GHz (x-axis) for different operating states of the switch 110 of the superconducting switch circuit 100 of FIG. 1. In particular, the simulated S₂₁ scattering parameters 301 show insertion loss for RF signal transmission over the transmission line 130 (from the first (input) port P₁ to the second (output) port P₂) for a range of RF frequencies from 1.0 GHz to 10.0 GHz, under an operating state of the switch 110 in which the DC-SQUID 112 is biased in a high inductance state with a net effective magnetic flux bias of Φ_{bias}=0.5 Φ₀ threaded through the superconducting loop of the DC-SQUID 112 of the switch 110. Moreover, the simulated S₂₁ scattering parameters 302 show the insertion loss for RF signal transmission over the transmission line 130 (from the first port P₁ to the second port P₂) for the range of RF frequencies from 1.0 GHz to 10.0 GHz, under an operating state of the switch 110 in which the DC-SQUID 112 is biased in a low inductance state with a net effective magnetic flux bias of Φ_{bias}=0 threaded through the superconducting loop of the DC-SQUID 112. The simulations are based at least in part on the DC-SQUID 112 having a critical current I_{CO}=10 μA.

As shown in FIG. 3A, the simulated S₂₁ scattering parameters 301 show an insertion loss (S₂₁) of 0 dB for the range of RF frequencies from 1.0 GHz to 10.0 GHz, under the operating state in which the DC-SQUID 112 is biased in the high inductance state. As noted above, in the high inductance state, the DC-SQUID 112 of the switch 110 is, in effect, an RF open to ground, resulting in the matched impedance Z₀ of the first and second ports P₁ and P₂ allowing full transmission (unity transmission) of the energy of an RF input signal over the transmission line 130 from the first port P₁ to the second port P2.

On the other hand, as shown in FIG. 3A, the simulated S₂₁ scattering parameters 302 show an insertion loss (S₂₁) of 25 dB or more for the range of RF frequencies from 1.0 GHz to 10.0 GHz, under the operating state of the switch 110 in which the DC-SQUID 112 is biased in the low inductance state. As noted above, in the low inductance state, the DC-SQUID 112 is, in effect, a low inductance shunt to ground, which breaks the impedance match between the first and second ports P₁ and P₂, resulting in the reflection of energy of RF input signal back to the input port, thereby blocking the RF input signal applied to the first (input) port P₁ from being transmitted to the second port P2.

Next, FIG. 3B is a graph 310 which illustrates simulated S₂₁ scattering parameters 311 that show insertion loss (S₂₁) in terms of power in dB (y-axis) as a function of an applied flux,

$$\frac{{Φ}_{bias}}{{Φ}_{0}} ( x - axis ) ,$$

for an RF signal with a frequency of 5.0 GHz. FIG. 3B shows that the insertion loss S₂₁ dynamically changes from approximately −35.0 dB

$$( when \frac{{Φ}_{bias}}{{Φ}_{0}} = 0. ) ,$$

to 0 dB

$$( when \frac{{Φ}_{bias}}{{Φ}_{0}} = 0.5 ) .$$

The simulated S₂₁ scattering parameters 311 illustrate that the impedance matching between the first and second ports P₁ and P₂ dynamically changes as a function of the magnetic flux Φ_{bias} through the superconducting loop of the DC-SQUID 112, as the inductance of the DC-SQUID 112 transitions from a low inductance state to a high inductance state.

Next, FIG. 3C is a graph 320 which illustrates simulated S₂₁ scattering parameters 321 and 322 that show insertion loss (S₂₁) in terms of power in dB (y-axis) as a function of frequency in GHz (x-axis) over the frequency range from 1.0 GHz to 10.0 GHz for different operating states of the switch 210 of the superconducting switch circuit 200 of FIG. 2. In particular, the simulated S₂₁ scattering parameters 321 show the insertion loss for RF signal transmission over the transmission line 130 (from the first (input) port P₁ to the second (output) port P₂) under an operating state of the switch 210 in which the first and second DC-SQUIDs 212-1 and 212-2 are both biased in a high inductance state with a net effective magnetic flux bias of Φ_{bias}=0.5 (Do threaded through the superconducting loops of the first and second DC-SQUIDs 212-1 and 212-2. Moreover, the simulated S₂₁ scattering parameters 322 show the insertion loss for RF signal transmission over the transmission line 130 (from the first port P₁ to the second port P₂) under an operating state of the switch 210 in which the first and second DC-SQUIDs 212-1 and 212-2 are both biased in a low inductance state with a net effective magnetic flux bias of Φ_{bias}=0 threaded through the superconducting loops of the first and second DC-SQUIDs 212-1 and 212-2.

As shown in FIG. 3C, the simulated S₂₁ scattering parameters 321 show an insertion loss (S₂₁) of 0 dB over the frequency range from 1.0 GHz to 10.0 GHz, under the operating state of the switch 210 in which the first and second DC-SQUIDs 212-1 and 212-2 are both biased in the high inductance state. As noted above, in the high inductance state, both of the first and second DC-SQUIDs 212-1 and 212-2 of the switch 210 are, in effect, an RF open to ground. This results in maintaining the matched impedance Z₀ of the first and second ports P₁ and P₂ and thereby allowing full transmission (unity transmission) of the energy of an RF input signal over the transmission line 130 from the first port P₁ to the second port P₂.

On the other hand, as shown in FIG. 3C, the simulated S₂₁ scattering parameter 322 show an insertion loss (S₂₁) of about 35 dB or more over the frequency range from 1.0 GHz to 10.0 GHz, under the operating state of the switch 210 in which the first and second DC-SQUIDs 212-1 and 212-2 are both biased in the low inductance state. As noted above, in the low inductance state, both of the first and second DC-SQUIDs 212-1 and 212-2 of the switch 210 are, in effect, a low inductive shunt to ground. This results in breaking the impedance matching between the first and second ports P₁ and P₂, resulting in the reflection of energy of the RF input signal back to the input port (e.g., port P₁), thereby blocking the RF input signal applied to the first (input) port P₁ from being transmitted to the second (output) port P₂.

For illustrative and comparative purposes, FIG. 3C shows the simulated S₂₁ scattering parameters 302 of the insertion loss (S₂₁) that is achieved over the frequency range from 1.0 GHz to 10.0 GHz, under the operating state of the switch 110 when the single DC-SQUID 112 is biased in the low inductance state. A comparison between the simulated S₂₁ scattering parameters 302 and 323 shows that the implementation of the switch 210 with at least two parallel DC-SQUIDs (e.g., the first and second DC-SQUIDS 212-1 and 212-2) connected to ground GND provides an increased amount of S₂₁ rejection, e.g., about 10 dB to 15 dB of additional S₂₁ rejection by implementing the switch 210 with two parallel DC-SQUIDs to ground (FIG. 2) as compared to implementing the switch 110 with a single DC-SQUID to ground (FIG. 1). Indeed, as compared to the switch 110 with the single DC-SQUID 112, the addition of the second DC-SQUID 212-2 further reduces the shunt inductance when the two DC-SQUIDs 212-1 and 212-2 are biased in the low inductance state, since the shunt inductances of the first and second DC-SQUIDs 212-1 and 212-2 are connected in parallel to ground, resulting in an effective shunt inductance which is ½ of the inductance of the individual first and second DC-SQUIDs 212-1 and 212-2 thus, providing a better ON/OFF ratio of the switch 210.

It is to be appreciated that the functionality of the exemplary superconducting switch circuits 100 and 200 of FIGS. 1 and 2 can be extended to provide dynamic RF pulse shaping using dynamic flux bias control signals. For example, as noted above, the flux bias control signal generator 120 (e.g., FIGS. 1 and 2) is configured to generate a dynamic flux bias control signal (Flux_Pulse). In an exemplary embodiment, the dynamic flux bias control signal (Flux_Pulse) is configured to (i) flux bias the DC-SQUIDs of the switches 110 and 112 into high inductance states to allow the transmission of an RF signal over the transmission line 130 between the first and second ports P₁ and P₂ and to (ii) operate as a modulating signal to amplitude modulate the RF signal that is input to the transmission line 130 to thereby generate an amplitude modulated RF signal (or pulse-shaped RF signal) that is output from the transmission line 130.

For example, FIG. 4 illustrates an amplitude modulated RF signal 400 that can be generated by controlling of a superconducting switch circuit using a dynamic flux bias control signal, according to an exemplary embodiment of the disclosure. In particular, FIG. 4 illustrates an exemplary embodiment of utilizing a dynamic flux bias control signal having a square pulse profile to (i) flux bias the DC-SQUID 112 of the switch 110 into high inductance state to allow the transmission of an RF signal (e.g., 5 GHz signal) over the transmission line 130 from the first port P₁ to the second port P₂ and to (ii) and modulate the input RF signal to generate the amplitude modulated RF signal 420 which is output from the second port P₂. In the exemplary embodiment shown in FIG. 4, the dynamic flux bias control signal (Flux_Pulse) is assumed to be a square pulse having a pulse duration from t1 to t2, wherein the resulting amplitude modulated RF signal 400 comprises an envelope which corresponds to the square pulse profile of the dynamic flux bias control signal.

While FIG. 4 shows an exemplary embodiment in which a dynamic flux bias control signal (Flux_Pulse) is generated with a square pulse profile, in other embodiments, the dynamic flux bias control signal (Flux_Pulse) can be generated using other pulse profiles, e.g., Gaussian pulse profile, etc., to generate amplitude modulated RF signals with pulse-shaped envelopes that are suitable for a given application or quantum operation (e.g., driving a superconducting qubit). In this regard, the exemplary superconducting switch circuits as discussed here can be utilized to perform RF pulse shaping within a dilution refrigerator. In this regard, the ability to in-situ dynamically pulse shape RF tones that are applied to, e.g., superconducting qubits to perform gate operations, would provide extra benefits in gate fidelity.

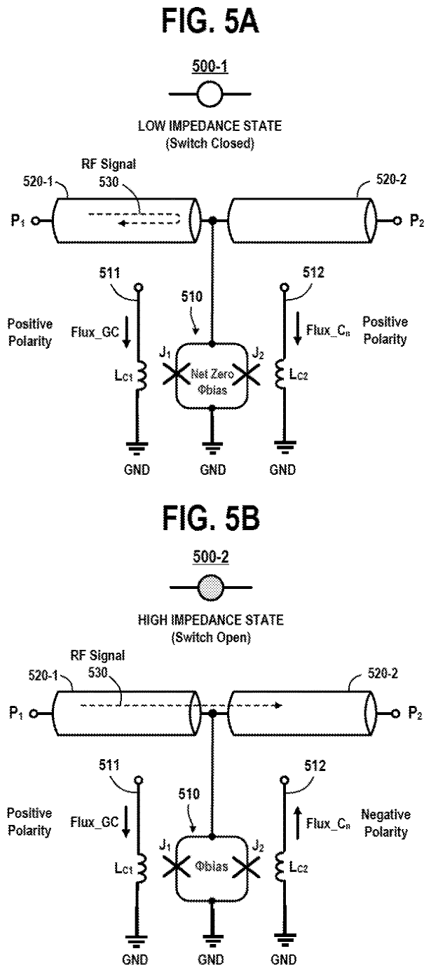

FIGS. 1 and 2 illustrate exemplary embodiments in which the switches 110 and 210 are controlled using a single flux bias control signal. In other embodiments, a given switch can be flux biased and controlled using two flux bias control signals, exemplary embodiments of which are shown in FIGS. 5A and 5B. For example, FIGS. 5A and 5B schematically illustrate methods for controlling a switch using two flux bias control signals to selectively place the switch into a low impedance state 500-1 or a high impedance state 500-2, according to an exemplary embodiment of the disclosure. In particular, FIGS. 5A and 5B illustrate methods for flux-tuning a switch 510 (or switch node 510) having a DC-SQUID architecture which, as discussed above, comprises a superconducting loop which comprises at least two Josephson junctions including a first Josephson junction J1 and a second Josephson junction J2, which have non-linear inductances.

The switch node 510 is disposed adjacent to a first coupling inductor L_{C1} and a second coupling inductor L_{C2}. The first coupling inductor L_{C1} is connected in series (inline) with a first control line 511 (or global control line), and the second coupling inductor L_{C2} is connected in series (inline) with a second control line 512. The switch 510 is coupled to a given point between a first transmission line 520-1 and a second transmission line 520-2 (or at a given point along the same transmission line) between first and second ports P₁ and P₂, and provides an inductive shunt to ground GND. It is assumed that the first and second transmission lines 520-1 and 520-2 and the first and second ports P₁ and P₂ have the same nominal characteristic impedance Z₀.

FIG. 5A schematically illustrates a first state (e.g., low impedance state 500-1) of the switch node 510 which results from applying a first flux bias control signal (denoted Flux_GC) on the first (global) control line 511, and applying a second flux bias control signal (denoted Flux_Cₙ) on the second control line 512, wherein the first and second flux bias controls Flux_GC and Flux_Cₙ have the same polarities (e.g., positive polarity). In this instance, switch node 510 is flux biased in a low impedance state (e.g., low inductance state) because the magnetic fluxes, which are generated by the respective first and second coupling inductors L_{C1} and L_{C2}, are threaded through the superconducting loop of the switch node 510 in opposite directions, resulting in a net-zero amount of magnetic flux bias (e.g., Φ_{bias}=0 or Φ_{bias}≈0) through the superconducting loop of the switch node 510. In the low impedance state 500-1, the switch node 510 breaks the impedance matching between first and second ports P₁ and P₂, which causes an RF signal 530, which in input to the first port P₁ to be reflected back to the first port P₁ (as schematically shown in FIG. 5A) and thereby block the transmission of the RF signal 530 along the transmission line 520-2 to the second port P₂.

In particular, based on the “right hand rule” of magnetism, the positive polarity of the first flux bias control signal Flux_GC results in a positive current flow through the first coupling inductor L_{C1}, which causes the first coupling inductor L_{C1} to generate a magnetic flux that flows through the superconducting loop of the switch node 510 in a direction out of the plane of the drawing sheet. On the other hand, the positive polarity of the second flux bias control signal Flux_Cₙ results in a positive current flow through the second coupling inductor L_{C2}, which causes the second coupling inductor L_{C2} to generate a magnetic flux that flows through the superconducting loop of the switch node 510 in a direction into the plane of the drawing sheet. Assuming that the magnetic fluxes generated by the respective first and second coupling inductors L_{C1} and L_{C2}, have the same or substantially the same magnitude, the magnetic fluxes which are threaded through the superconducting loop of the switch node 510 in opposite directions, effectively cancelling each other, resulting in a net-zero amount (or near net-zero amount) of magnetic flux bias Φ_{bias} which causes the switch node 510 to be biased in a low impedance state 500-1 (or low inductance state) as represented by a non-shaded circle shown in FIG. 5A.

On the other hand, FIG. 5B schematically illustrates a second state (e.g., high impedance state 500-2) of the switch node 510 which results from applying the first flux bias control signal Flux_GC on the first control line 511 with a first polarity (e.g., positive polarity), while applying the second flux bias control signal Flux_Cn on the second control line 512 with an opposite polarity (e.g., negative polarity). In this instance, switch node 510 is placed in a high impedance state (e.g., high inductance state) because the magnetic fluxes generated by the respective first and second coupling inductors L_{C1} and L_{C2}, are threaded through the superconducting loop of the switch node 510 in the same direction. As a result, magnetic fluxes generated by the respective first and second coupling inductors L_{C1} and L_{C2} are added together, resulting in a net amount of magnetic flux bias, e.g., Φ_{bias}=0.5 Φ₀ or Φ_{bias}≈0.5 Φ₀, which causes the switch node 510 to be biased in the high impedance state 500-2 (or high inductance state). In the high impedance state, the switch node 510 effectively comprises an RF open to ground, which allows the RF signal 530 to be transmitted from the first port P₁ to the second port P₂ over the first and second transmission lines 520-1 and 520-2.

In particular, based on the “right hand rule” of magnetism, the positive polarity of the first flux bias control signal Flux_GC results in positive current flow through the first coupling inductor L_{C1}, which causes the first coupling inductor L_{C1} to generate a magnetic flux which flows through the superconducting loop of the switch node 510 in a direction out of the plane of the drawing sheet. Further, the negative polarity of the second flux bias control signal Flux_Cn results in a negative current flow through the second coupling inductor L_{C2}, which causes the second coupling inductor L_{C2} to generate a magnetic flux which flows through the superconducting loop of the switch node 510 in a direction out of the plane of the drawing sheet. As a result, the magnetic fluxes which are threaded through the superconducting loop of the switch node 510 in the same direction are combined, resulting in a net amount of magnetic flux bias (e.g., Φ_{bias}=0.5 Φ₀), causing the switch node 510 to be biased in a high impedance state 500-2 (or high inductance state) as represented by a shaded circle shown in FIG. 5B.

It is to be noted that the terms “positive polarity” or “positive current” as used herein denote a current flow in a direction along a flux bias control line from a flux bias control signal generator to a ground node GND. For example, as schematically illustrated in FIG. 5B, the arrow next to the first control line 511 (flux bias control line) represents a “positive current” flow of the flux bias control signal Flux_GC on the first control line 511, which flows in a direction from a flux bias control signal generator to the ground node GND. On the other hand, the terms “negative polarity” or “negative current” as used herein denote a current flow in a direction along a flux bias control line from the ground node GND to a flux bias control signal generator. For example, as schematically illustrated in FIG. 5B, the arrow next to the second control line 512 (flux bias control line) represents a “negative current” flow of the flux bias control signal Flux_Gₙ on the second control line 512, which flows in a direction from the ground node GND to a flux bias control signal generator.

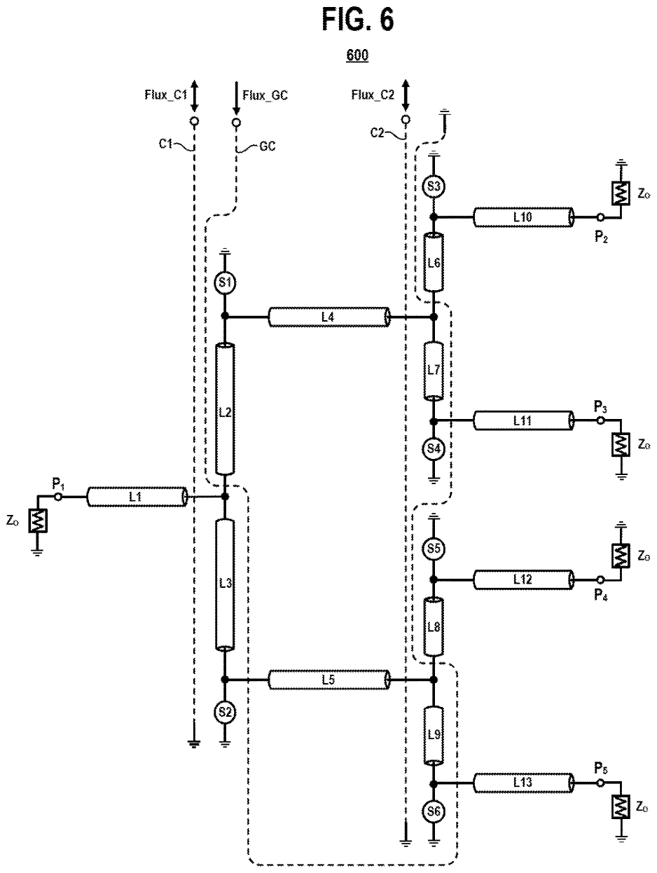

FIG. 6 schematically illustrates a superconducting switch circuit, according to another exemplary embodiment of the disclosure. In particular, FIG. 6 schematically illustrates a superconducting switch circuit 600 which comprises a plurality of input/output ports P₁, P₂, P₃, P₄, and P₅, a plurality of switch nodes S1, S2, S3, S4, S5, and S6, a plurality of transmission lines L1, L2, L3, L4, L5, L6, L7, L8, L9, L10, L11, L12, and L13, and a plurality of flux bias control lines including a global control line GC and a plurality of local control lines, e.g., a first local control line C1 and a second local control line C2. As explained in further detail below, the superconducting switch circuit 600 comprises an exemplary architecture which allows a signal routing path to be selectively configured between the port P₁ and any other one of the other ports P₂, P₃, P₄, and P₅, by applying appropriate flux bias control signals on the global control line GC and the local control lines C1 and C2 to bias the switch nodes S1, S2, S3, S4, S5, and S6 into low or high inductance states, as needed, to configure a desired signal routing path through the superconducting switch circuit 600.

In an exemplary embodiment, each switch node S1, S2, S3, S4, S5, and S6 comprises at least one DC-SQUID or multiple parallel connected DC-SQUIDS. More specifically, in some embodiments, the switch nodes S1, S2, S3, S4, S5, and S6 are implemented using the exemplary architecture of the switch 110 of FIG. 1, or the exemplary architecture of the switch 210 of FIG. 2. In this regard, for ease of illustration, the switch nodes S1, S2, S3, S4, S5, and S6 are generically depicted in FIG. 6 as circles, although it is to be understood that each of the switch nodes S1, S2, S3, S4, S5, and S6 would include one or more superconducting loops with Josephson junctions, and coupling inductors disposed in adjacent proximity to the superconducting loop(s) thereof.

As schematically illustrated in FIG. 6, the switch node S1 provides an inductive shunt to ground at a point between the transmission lines L2 and L4. The switch node S2 provides an inductive shunt to ground at a point between the transmission lines L3 and L5. The switch node S3 provides an inductive shunt to ground at a point between the transmission lines L6 and L10. The switch node S4 provides an inductive shunt to ground at a point between the transmission lines L7 and L11. The switch node S5 provides an inductive shunt to ground at a point between the transmission lines L8 and L12. The switch node S6 provides an inductive shunt to ground at a point between the transmission lines L9 and L13. It is assumed that each of the transmission lines L1-L13 and the I/O ports P₁-P₅ have the same nominal characteristic impedance Z₀ (e.g., Z₀=50Ω).

In the exemplary switch architecture shown in FIG. 6, each switch node S1, S2, S3, S4, S5, and S6 is flux-controlled by two (2) flux bias control signals applied on two (2) flux bias control lines that are disposed adjacent to the given switch node. In particular, each switch node S1, S2, S3, S4, S5, and S6 is globally controlled by the global control line GC, which is routed through the superconducting switch circuit 600 and configured to apply a global flux bias control signal Flux_GC to each switch node S1, S2, S3, S4, S5, and S6. In an exemplary embodiment, the global flux bias control signal Flux_GC comprises a DC current which flows on the global control line GC with a fixed positive polarity (as indicated by the arrow shown in FIG. 6) to cause a global magnetic flux bias Φ_{g_bias} (i.e., Φ_{g_bias}=0.25 Φ₀ or Φ_{g_bias}≅0.25 Φ₀) to be threaded through each superconducting loop of each DC-SQUID of each switch node S1, S2, S3, S4, S5, and S6.

Moreover, the switch nodes S1 and S2 are commonly controlled by the first local control line C1 which is routed through the superconducting switch circuit 600 and configured to apply a first local flux bias control signal Flux_C1 to each switch node S1 and S2. In an exemplary embodiment, the first local flux bias control signal Flux_C1 comprises a DC current which flows on the first local control line C1 with either a positive polarity or negative polarity (as indicated by the double arrow shown in FIG. 6) to cause a magnetic flux bias Φ_{1_bias} (i.e., Φ_{1_bias}=0.25 Φ₀ or Φ_{1_bias}≅0.25 Φ₀,) to be threaded through each superconducting loop of each DC-SQUID of each switch node S1 and S2. The magnetic flux bias Φ_{1_bias} either (i) adds with Φ_{g_bias} to place the given switch node in a high inductance state or (ii) cancels Φ_{g_bias} to place the given switch node in a low inductance state.

Similarly, the switch nodes S3, S4, S5, and S6 are commonly controlled by the second local control line C2 which is routed through the superconducting switch circuit 600 and configured to apply a second local flux bias control signal Flux_C2 to each switch node S3, S4, S5, and S6. In an exemplary embodiment, the second local flux bias control signal Flux_C2 comprises a DC current which flows on the second local control line C2 with either a positive polarity or negative polarity (as indicated by the double arrow shown in FIG. 6) to cause a magnetic flux bias Φ_{2_bias} (i.e., Φ_{2_bias}=0.25 Φ₀ or Φ_{2_bias}≅0.25 Φ₀,) to be threaded through each superconducting loop of each DC-SQUID of each switch node S3, S4, S5, and S6. The magnetic flux bias Φ_{2_bias} either (i) adds with Φ_{g_bias} to place the given switch node in a high inductance state or (ii) cancels Φ_{g_bias} to place the given switch node in a low inductance state.

More specifically, in the exemplary switch architecture shown in FIG. 6, a given one of the switch nodes S1 and S2 will be flux biased in a high inductance state or a low inductance state depending on (i) the polarities of the global flux bias control signal Flux_GC and the first local flux bias control signal Flux_C1, and the locations of the control lines GC and C1 with respect to the given switch node. Similarly, a given one of the switch nodes S3, S4, S5, and S6 will be flux biased in a high inductance state or a low inductance state depending on (i) the polarities of the global flux bias control signal Flux_GC and the second local flux bias control signal Flux_C2, and the locations of the control lines GC and C2 with respect to the given switch node.

In particular, for each switch node (e.g., S1, S3, and S5) having the global control line GC and the respective local control line (e.g., C1 or C2) disposed on the same side of the switch, the switch node will be flux biased in either (i) a low inductance state, when the polarities of the global flux bias control signal Flux_GC and the respective local flux bias control signal (e.g., Flux_C1 or Flux_C2) are opposite (e.g., one negative and one positive), or (ii) a high inductance state, when the polarities of the global flux bias control signal Flux_GC and the respective local flux bias control signal (e.g., Flux_C1 or Flux_C2) are the same (e.g., both positive). On the other hand, for each switch node (e.g., S2, S4, and S6) having the global control line GC and the respective local control line (e.g., C1 or C2) disposed on different sides of the switch node, the switch node will be flux biased in either (i) a low inductance state, when the polarities of the global flux bias control signal Flux_GC and the respective local flux bias control signal (e.g., Flux_C1 or Flux_C2) are the same (e.g., both positive), or (ii) a high inductance state, when the polarities of the global flux bias control signal Flux_GC and the respective local flux bias control signal (e.g., Flux_C1 or Flux_C2) are opposite.

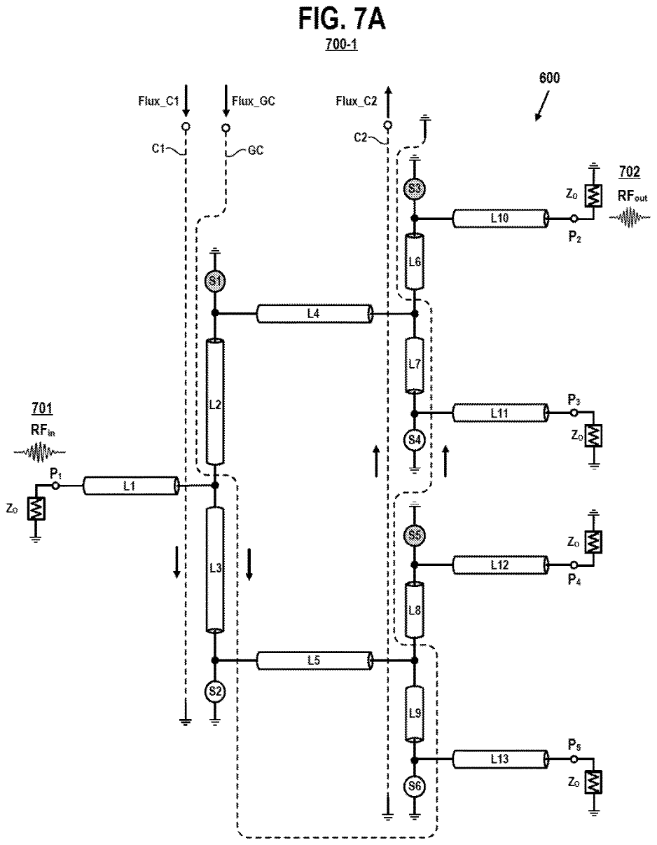

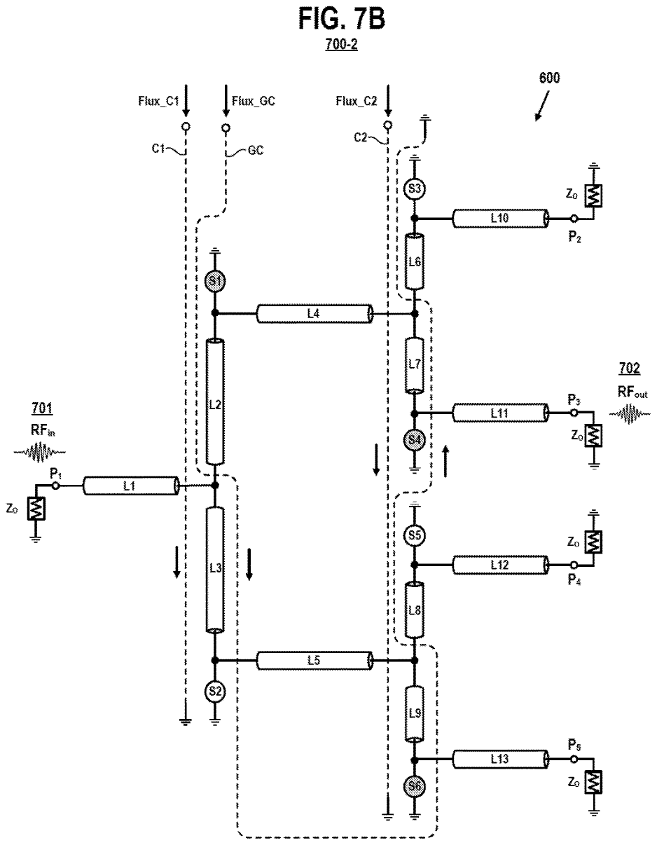

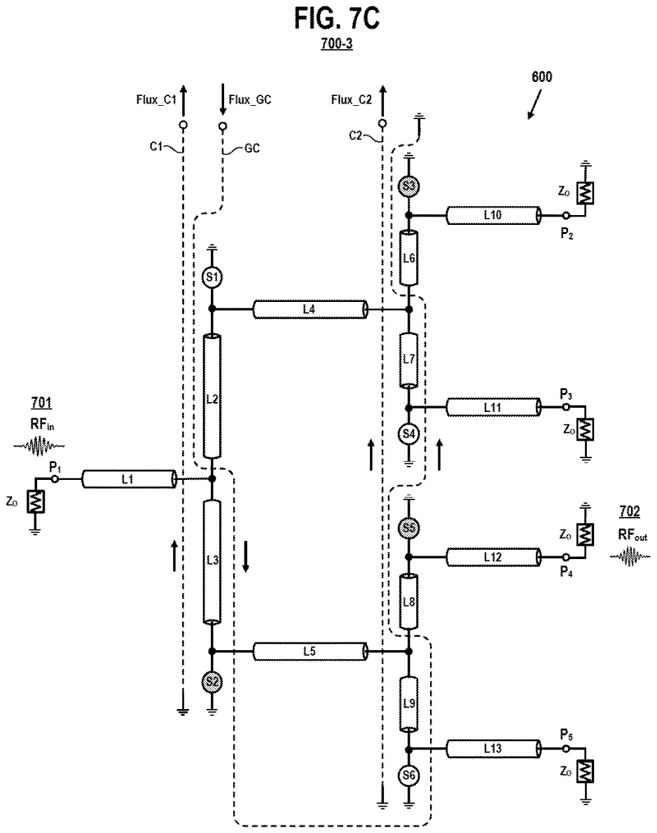

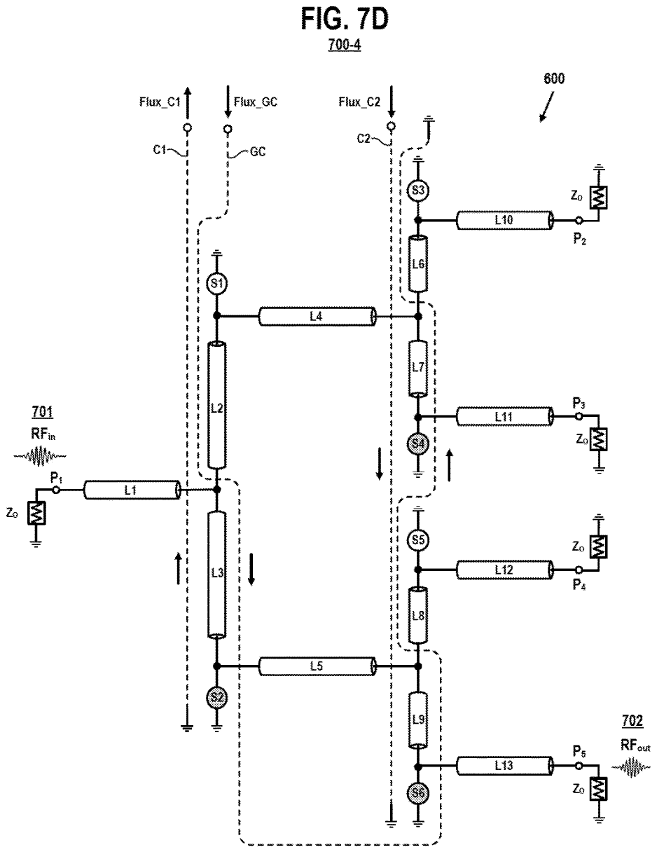

In operation of the superconducting switch circuit 600, the flux bias control signals Flux_GC, Flux_C1, and Flux_C2 are applied on the respective flux bias control lines GC, C1, and C2 with appropriate polarities to flux bias each switch node S1, S2, S3, S4, S5, and S6 in a respective low inductance or high inductance and, thereby, selectively configure a signal routing path between the port P₁ and one of the other ports P₂, P₃, P₄, and P₅. The superconducting switch circuit 600 comprises a reciprocal switch architecture, which allows the superconducting switch circuit 600 to be utilized as (i) a multiplexing switch (e.g., 4-to-1 relay) in which the ports P₂, P₃, P₄, and P₅ are implemented as four (4) signal input ports, and the port P₁ is implemented as a signal output port, or (ii) a demultiplexing switch (e.g., 1-to-4 relay) in which the port P₁ is implemented as a signal input port, and the ports P₂, P₃, P₄, and P₅ are implemented as four (4) signal output ports. For purposes of illustration, FIGS. 7A, 7B, 7C, and 7D schematically illustrate exemplary modes of operation of the superconducting switch circuit 600 of FIG. 6, according to exemplary embodiment of the disclosure in which superconducting switch circuit 600 is utilized as a demultiplexing switch (e.g., 1-to-4 relay).

For example, FIG. 7A schematically illustrates an exemplary mode of operation 700-1 of the superconducting switch circuit 600 in which a signal routing path is selectively configured between the ports P₁ and P₂, wherein an input RF signal 701 applied to the port P₁ is output from the port P₂ as an output RF signal 702. In particular, FIG. 7A shows an exemplary mode of operation in which each switch node S1, S3, and S5 is flux biased in a high inductance state (as indicated by the shaded circles), while each switch node S2, S4, and S6 is flux biased in a low inductance state (as indicated by the non-shaded circles). The exemplary mode of operation 700-1 is achieved by applying a global flux bias control signal Flux_GC with a positive polarity to the global control line GC, applying a first local flux bias control signal Flux_C1 with a positive polarity to the first local control line C1, and applying a second local flux bias control signal Flux_C2 with a negative polarity to the second local control line C2.

With each of the switch nodes S1 and S3 flux biased in a high inductance state (essentially providing an RF open to ground at the connection point between the transmission lines L2 and L4, and at the connection point between the transmission lines L6 and L10), an impedance matched signal routing path is configured from the input port P₁ to the output port P₂ along the transmission lines L1, L2, L4, L6, and L10. On the other hand, with the switch node S4 flux biased in a low inductance state, a low impedance shunt to ground exists at the connection point between the transmission lines L7 and L11, which blocks energy of the RF input signal from flowing onto the transmission line L11 towards the output port P₃. Similarly, with the switch node S2 flux biased in a low inductance state, a low impedance shunt to ground exists at the connection point between the transmission lines L3 and L5, which blocks energy of the input RF signal 701 from flowing onto the transmission line L5 towards the output ports P₄ and P₅. In this regard, although the switch node S5 is flux biased in a high inductance state, the port P₄ is essentially decoupled from the input port P₁ by virtue of the low inductance shunt to ground provided by the switch node S2 being flux biased in the low inductance state.

Next, FIG. 7B schematically illustrates an exemplary mode of operation 700-2 of the superconducting switch circuit 600 in which a signal routing path is selectively configured between the ports P₁ and P₃, wherein an input RF signal 701 applied to the port P₁ is output from the port P₃ as an output RF signal 702. In particular, FIG. 7B shows an exemplary mode of operation in which each switch node S1, S4, and S6 is flux biased in a high inductance state (as indicated by the shaded circles), while each switch node S2, S3, and S5 is flux biased in a low inductance state (as indicated by the non-shaded circles). The exemplary mode of operation 700-2 is achieved by applying a global flux bias control signal Flux_GC with a positive polarity to the global control line GC, applying a first local flux bias control signal Flux_C1 with a positive polarity to the first local control line C1, and applying a second local flux bias control signal Flux_C2 with a positive polarity to the second local control line C2.

With each of the switch nodes S1 and S4 flux biased in a high inductance state (essentially providing a RF open to ground at the connection point between the transmission lines L2 and L4, and at the connection point between the transmission lines L7 and L11), an impedance matched signal routing path is configured from the input port P₁ to the output port P₃ along the transmission lines L1, L2, L4, L7, and L11. On the other hand, with the switch node S3 flux biased in a low inductance state, a low impedance shunt to ground exists at the connection point between the transmission lines L6 and L10, which blocks energy of the RF input signal from flowing onto the transmission line L10 towards the output port P₂. Similarly, with the switch node S2 flux biased in a low inductance state, a low impedance shunt to ground exists at the connection point between the transmission lines L3 and L5, which blocks energy of the RF input signal from flowing onto the transmission line L5 towards the output ports P₄ and P₅. In this regard, while the switch node S6 is flux biased in a high inductance state, the port P₅ is essentially decoupled from the input port P₁ by virtue of the low inductance shunt to ground provided by the switch node S2 being flux biased in the low inductance state.

Next, FIG. 7C schematically illustrates an exemplary mode of operation 700-3 of the superconducting switch circuit 600 in which a signal routing path is selectively configured between the ports P₁ and P₄, wherein an input RF signal 701 applied to the port P₁ is output from the port P₄ as an output RF signal 702. In particular, FIG. 7C shows an exemplary mode of operation in which each switch node S2, S3, and S5 is flux biased in a high inductance state (as indicated by the shaded circles), while each switch node S1, S4, and S6 is flux biased in a low inductance state (as indicated by the non-shaded circles). The exemplary mode of operation 700-3 is achieved by applying a global flux bias control signal Flux_GC with a positive polarity to the global control line GC, applying a first local flux bias control signal Flux_C1 with a negative polarity to the first local control line C1, and applying a second local flux bias control signal Flux_C2 with a negative polarity to the second local control line C2.

With each of the switch nodes S2 and S5 flux biased in a high inductance state (essentially providing an RF open to ground at the connection point between the transmission lines L3 and L5, and at the connection point between the transmission lines L8 and L12), an impedance matched signal routing path is configured from the input port P₁ to the output port P₄ along the transmission lines L1, L3, L5, L8, and L12. On the other hand, with the switch node S6 flux biased in a low inductance state, a low impedance shunt to ground exists at the connection point between the transmission lines L9 and L13, which blocks energy of the RF input signal from flowing onto the transmission line L13 towards the output port P₅. Similarly, with the switch node S1 flux biased in a low inductance state, a low impedance shunt to ground exists at the connection point between the transmission lines L2 and L4, which blocks energy of the input RF signal 701 from flowing onto the transmission line L2 towards the output ports P₂ and P₃. In this regard, although the switch node S3 is flux biased in a high inductance state, the port P₂ is essentially decoupled from the input port P₁ by virtue of the low inductance shunt to ground provided by the switch node S1 being flux biased in the low inductance state.

Next, FIG. 7D schematically illustrates an exemplary mode of operation 700-4 of the superconducting switch circuit 600 in which a signal routing path is selectively configured between the ports P₁ and P₅, wherein an input RF signal 701 applied to the port P₁ is output from the port P₅ as an output RF signal 702. In particular, FIG. 7D shows an exemplary mode of operation in which each switch node S2, S4, and S6 is flux biased in a high inductance state (as indicated by the shaded circles), while each switch node S1, S3, and S5 is flux biased in a low inductance state (as indicated by the non-shaded circles). The exemplary mode of operation 700-4 is achieved by applying a global flux bias control signal Flux_GC with a positive polarity to the global control line GC, applying a first local flux bias control signal Flux_C1 with a negative polarity to the first local control line C1, and applying a second local flux bias control signal Flux_C2 with a positive polarity to the second local control line C2.

With each of the switch nodes S2 and S6 flux biased in a high inductance state (essentially providing an RF open to ground at the connection point between the transmission lines L3 and L5, and at the connection point between the transmission lines L9 and L13), an impedance matched signal routing path is configured from the input port P₁ to the output port P₅ along the transmission lines L1, L3, L5, L9, and L13. On the other hand, with the switch node S5 flux biased in a low inductance state, a low impedance shunt to ground exists at the connection point between the transmission lines L8 and L12, which blocks energy of the RF input signal from flowing onto the transmission line L12 towards the output port P₄. Similarly, with the switch node S1 flux biased in a low inductance state, a low impedance shunt to ground exists at the connection point between the transmission lines L2 an L4, which blocks energy of the input RF signal 701 from flowing onto the transmission line L2 towards the output ports P₂ and P₃. In this regard, although the switch node S4 is flux biased in a high inductance state, the output port P₃ is essentially decoupled from the input port P₁ by virtue of the low inductance shunt to ground provided by the switch node S1 being flux biased in the low inductance state.

It is to be noted that FIG. 6 schematically illustrates an exemplary embodiment of a superconducting switch circuit 600 which comprises a plurality of switch nodes S1-S6 and control lines GC, C1, and C2, an input port (e.g., port P₁) and a plurality of output ports (e.g., ports P₂-P₅), wherein the ports P₁-P₅ have matched impedances. In addition, the superconducting switch circuit 600 comprises a plurality of signal transmission paths, wherein each signal transmission path couples the input port (e.g., port P₁) to a respective one of the output ports (P₂-P₅). In the exemplary embodiment of FIG. 6, the superconducting switch circuit 600 comprises four signal transmission paths including (i) a first signal transmission path comprising transmission lines L1, L2, L4, L6, and L10, which couple the ports P₁ and P₂, (ii) a second signal transmission path comprising transmission lines L1, L2, L4, L7, and L11, which couples the ports P₁ and P₃, (iii) a third signal transmission path comprising transmission lines L1, L3, L5, L8, and L12, which couples the ports P₁ and P₄, and (iv) a fourth signal transmission path comprising transmission lines L1, L3, L5, L9, and L13, which couples the ports P₁ and P₅. Moreover, as shown in FIGS. 7A-7B, the control lines GC, C1, and C2 are configured to apply flux bias control signals to the switch nodes S1-S6 to selectively enable any one of the signal transmission paths to couple the (input) port P₁ to any one of the other (output) ports P₂ and P₅, in response to the flux bias control signals applied to the switch nodes.

It is to be appreciated that the exemplary superconducting switching and signal routing circuits and systems as discussed herein are implemented with RF switches that are particularly advantageous for use with superconducting quantum computing systems. For example, the superconducting RF switches, which are formed of one or more parallel connected flux-tunable DC-SQUIDs, provide significantly fast on/off switching speeds, with large operating bandwidths, and high saturation power. In addition, the exemplary superconducting RF switches are low power, non-dissipative elements that would not generate heat within a dilution refrigerator (or cryostat).

Moreover, the exemplary superconducting RF switches and switching circuitry can be implemented for RF switching in signal routing paths to quickly couple and decouple a quantum processor (comprising an array of superconducting qubits) from control electronics and/or readout electronics, at will, depending on what part of the quantum algorithm is being executed during qubit gates. In addition, the exemplary superconducting RF switches allow for fast, dynamic decoupling of qubits from any external noise sources in the control and/or read out chains when performing qubit gate operations. In addition, as explained in further detail below, the exemplary superconducting RF switches can be utilized to implement a relatively large RF signal routing circuit architecture in which a single RF signal input can be selectively routed, via fast time domain multiplexing, to one of many superconducting quantum components devices in a given array (e.g., superconducting qubits of qubit array of quantum processor) for large scale quantum computing.

Moreover, it is to be further appreciated that the implementation of RF switching circuits with RF switches comprising one or more shunt impedance tunable elements (e.g., DC-SQUIDs) providing inductive shunts to ground provides various advantages over other superconducting RF switching schemes that implement a single shunt connected Josephson junction, a series connected DC-SQUID in an RF signal path, or a single series-connected Josephson junction in an RF signal path. For example, in an alternative embodiment, the exemplary switch nodes discussed herein can be disposed in series with the transmission lines, wherein a given series switch node on a transmission line can be placed in either (i) a low inductance state to allow the transmission of RF energy on the transmission line, or (ii) a high inductance state to block or suppress the transmission of RF energy on the transmission line. However, a series connected switch node can be problematic for various reasons.

For example, a series connected switch node (implemented using a DC-SQUID) can result in the generation of unwanted sideband frequency components due to 3-wave or 4-wave mixing as a result of the non-linearities of the Josephson junctions of the DC-SQUIDs. The generation of unwanted sideband frequency components in the RF signal transmission path can be detrimental to the RF signal since the generation of such sideband frequency components reduces the RF energy of the RF signal that is being transmitted, i.e., some of the RF energy of the target signal is imparted onto the sideband frequency signal components. In addition, a series connected switch node can lead to limited power input and overall limited power handling because the Josephson junctions have defined critical currents, and if overpowered, the Josephson junctions can transition from a superconducting state to a non-superconducting state, e.g., voltage state, which is not desirable. Moreover, high power RF transmission can result in 3 or 4 wave mixing, as noted above. On the other hand, the exemplary superconducting switch and signal routing circuits as discussed herein, implement ground-shunted superconducting switch nodes (as opposed to series connected switch nodes), which eliminates the issues of sideband signal generation and low power limitation, because the ground shunted superconducting switch nodes do not generate sideband signals and have better saturation power.

Some conventional RF switching techniques use a single Josephson junction as a switch that is coupled in series in a transmission line. An RF switch comprising a single Josephson junction that is series-connected in a transmission line is problematic for reasons discussed above (e.g., sideband generation, low saturation power). In addition, an RF switch comprising a single Josephson junction that is series-connected in the transmission line requires a filtering circuit to match the impedance of the single Josephson junction to the port impedances, wherein such filtering is not needed in the ground-shunted switch nodes as discussed herein. In addition, an RF switch comprising a single Josephson junction series-connected in a transmission line provides limited operating bandwidth, and renders is difficult to achieve a stable current flowing through the device as a function of the external flux, leading to unstable operation.

Some conventional RF switching techniques use a single Josephson junction as a switch that is ground-shunted to a transmission line. Such techniques are problematic for various reasons. For example, flux tuning a single Josephson junction requires a relatively large amount of flux bias current, e.g., 25 mA, to flux tune the impedance of the single Josephson junction into a high impedance state. In particular, a large amount of flux bias current is needed to generate a large amount of magnetic flux that can essentially penetrate the two parallel plates of metal which define the Josephson junction. In contrast, the exemplary switch nodes as described herein are implemented using a superconducting loop with Josephson junctions (e.g., DC-SQUID), wherein only a relatively small amount of flux bias current, e.g., ˜500 uA, is needed to flux tune the impedance of the DC-SQUID (e.g., tuning the inductance of the Josephson) into a high impedance state. Indeed, as noted above, a DC-SQUID can be flux tuned into a high impedance state with a magnetic flux of Φ_{bias}=0.5 Φ₀, which can be achieved with 500 uA flux bias control current.

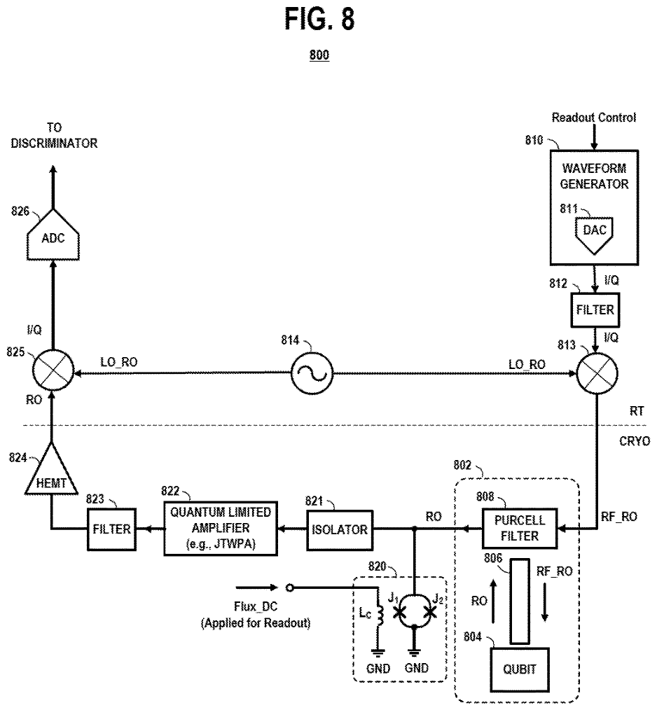

FIG. 8 schematically illustrates readout circuitry of a quantum processing system, which can implement a superconducting switch circuit in a qubit readout signal path to provide isolation, according to an exemplary embodiment of the disclosure. More specifically, FIG. 8 schematically illustrates qubit readout circuitry 800 of a quantum computing system which is configured to readout a quantum state of at least one superconducting qubit. For example, the qubit readout circuitry 800 comprises a qubit-resonator circuit 802 comprising a superconducting qubit 804, a readout resonator 806, and an optional Purcell filter 808, which is configured to enable a dispersive qubit readout operation.

The qubit readout circuitry 800 further comprises control circuitry that is configured to generate an RF readout control signal (RF_RO) to readout the state of the superconducting qubit 804 using a dispersive readout scheme which enables a quantum non-demolition measurement of the state of the superconducting qubit 804. For example, the qubit readout circuitry 800 comprises a control signal chain which comprises a waveform generator 810 (or pulse envelope generator) which comprises digital-to-analog (DAC) circuitry 811, low-pass filter circuitry 812, a first I/Q mixer 813 (upconverter or downconverter mixer), and a local oscillator (LO) signal generator 814.

In addition, the qubit readout circuitry 800 comprises a readout signal chain which comprises a superconducting switch circuit 820, an isolator 821, a quantum-limited amplifier (QLA) 822 (e.g., a Josephson traveling wave amplifier (JTWPA)), a filter 823, a high-electron-mobility-transistor (HEMT) amplifier 824, a second I/Q mixer 825, and analog-to-digital converter (ADC) circuitry 826, which outputs digital readout signals to a hardware or software-based discriminator to determine a readout state of the superconducting qubit 804. In an exemplary embodiment, the superconducting switch circuit 820 comprises a ground-shunt DC-SQUID (comprising a superconducting loop with Josephson junctions J1 and J2) and a coupling inductor L_{C} disposed in adjacent proximity to the DC-SQUID, wherein the ground-shunt DC-SQUID is coupled to a point in a signal transmission path between the qubit-resonator circuit 802 and the isolator 821.

The superconducting switch circuit 820 is controlled by a flux bias control signal Flux_DC, in a similar manner as discussed above for the superconducting switch 110 (FIG. 1). For example, the flux bias control signal Flux_DC comprises a current which, when applied, causes the coupling inductor L_{C} to generate a magnetic flux bias, e.g., Φ_{bias}=0.5 (Do which threads through the superconducting loop of the DC-SQUID of the superconducting switch circuit 820 and biases the DC-SQUID in a high inductance state. On the other hand, when the flux bias control signal Flux_DC is not asserted, the DC-SQUID is unbiased, e.g., magnetic flux bias Φ_{bias}=0, and the DC-SQUID is in a low inductance state.

The waveform generator 810 is configured to generate and output analog I and Q control signals with a given type of pulse envelope (e.g., Gaussian square pulse envelope) for qubit state readout, in response to a readout control signal. The analog I and Q control pulses are filtered by the low-pass filter circuitry 812. The filtered analog control I and Q control pulses are applied to the first I/Q mixer 813, along with an LO signal (LO_RO) that is generated by the LO signal generator 814, to generate an RF readout control pulse RF_RO. In particular, the first I/Q mixer 813 is configured mix the analog I and Q control pulses with the LO_Q signals of a given LO frequency (e.g., 7 GHz) to perform I/Q modulation and up-conversion and/or down-conversion using known techniques (e.g., single sideband modulation) to generate the RF readout control pulse RF_RO.

The RF readout control signal RF_RO is applied to an input port of the Purcell filter 808, and then coupled to the readout resonator 806. The readout resonator 806 is capacitively coupled to the superconducting qubit 804, thereby providing a qubit/resonator system. In some embodiments, the readout resonator 806 comprises a coplanar waveguide resonator. For a readout operation, in some embodiments, the center frequency of the RF readout control signal RF_RO corresponds to the resonant frequency of the readout resonator 806 to perform a dispersive qubit readout operation. In other embodiments, the frequency of RF_RO can be non-resonant with the readout resonator 806 and still provide information about the qubit state.

In the dispersive regime of qubit-resonator coupling, the RF readout control signal RF_RO (with the requisite frequency tone, pulse envelope shape, and pulse duration) interacts with the given qubit-resonator circuit 802 in a manner which results in the generation of readout signal RO that is reflected out from the readout resonator 806. The readout signal RO comprises information (e.g., phase and/or amplitude) that is qubit-state dependent. In other words, the dispersive readout process yields an RF readout signal RO having a state-dependent phasor response, which is analyzed to discriminate the quantum state of the superconducting qubit 804.

The readout signal RO is coupled to the Purcell filter 808, and then applied to the readout signal chain. The Purcell filter 808 is designed, for example, to pass at the frequency of the readout signal RO while blocking the transmission of energy at the qubit frequency, to enhance the qubit lifetime, and perform other functions as understood by those of ordinary skill in the art. The readout signal RO is coupled out to the readout signal chain where the readout signal RO flows through the isolator 821 and is applied to an input port of the QLA 822 which amplifies the readout signal RO. The amplified readout signal RO, which is output from the QLA 822, is filtered by the filter 823, flows through another optional isolator, is amplified by the HEMT amplifier 824, and then applied to an input of the second I/Q mixer 825. The second I/Q mixer 825 mixes the amplified and filtered RF readout signal RO with the LO_RO signal to perform a down conversion operation where the RF readout signal RO is down converted and split into analog I and Q signals. The analog I and Q signals are input to the ADC circuitry 826 and sampled by the ADC circuitry 826 to generate respective digital I and Q signals that are indicative of the amplitude and phase of the readout signal RO. A discriminator analyzes the digital I and Q signals to discriminate the measured quantum state of the superconducting qubit 804 based on the amplitude and phase components of the RF readout signal RO.

It is to be understood that FIG. 8 is an exemplary non-limiting embodiment which schematically illustrates a high-level schematic illustration of readout control circuitry. The qubit readout circuitry 800 and readout signal chain can be implemented using other components and configurations. Further, a frequency-multiplexed readout system (which implements frequency domain multiplexing) can be utilized to scale-up a readout chain in a quantum computing system for reading the quantum states of superconducting qubits in relatively large superconducting quantum computers. In a frequency-multiplexed readout system, multiple readout resonators (with different resonance frequencies) are coupled to separate qubits and commonly coupled to a communication bus. The communication bus is configured to allow the transmission of multiple readout signals with readout frequencies which match the resonance frequencies of the readout resonators, and, thus simultaneously read out the quantum states of multiple qubits using one input and one output line.

In the exemplary embodiment of FIG. 8, the isolator 821 is configured to isolate the qubit-resonator circuit 802 from back propagating signals from the downstream amplifiers 822 and 824 and electronics, which can adversely impact the qubit-resonator circuit 802 and other qubits and readout resonators of a quantum processor unit (QPU). In this regard, the isolator 821 provides a passive method for decoupling the QPU from the readout electronics. On the other hand, the superconducting switch circuit 820 is configured to provide dynamic decoupling and isolation of the QPU from the readout electronics.

For example, the QPU can be dynamically decoupled from the readout electronics by placing the DC-SQUID of the superconducting switch circuit 820 in a low inductance state (unbiased) during qubit gate operations such that any signal noise propagating backwards on the readout signal chain towards the QPU effectively sees a low inductive shunt to ground, or a mismatch in impedance, which causes the backpropagating noise to be reflected back away from the QPU. On the other hand, during a readout operation, the DC-SQUID of the superconducting switch circuit 820 is flux biased in a high inductance state, thereby allowing the impedance match between the QPU and the readout electronics to be reestablished and, thus, allow the RO signals to pass from the QPU to the downstream RO electronics.

While the exemplary embodiment of FIG. 8 illustrates the implementation of the superconducting switch circuit 820 comprising a single ground-shunted DC-SQUID, in other embodiments, a superconducting switch with multiple ground-shunted DC-SQUIDS connected in parallel (e.g., switch 210 of FIG. 2) can be implemented to provide dynamic decoupling/coupling of the QPU and readout electronics, providing greater signal isolation. Moreover, in some embodiments, a superconducting switch circuit with ground-shunted DC-SQUIDs can be used alone (in place of the isolator 821) to provide dynamic isolation with about 60 dB of rejection or more, without having to implement the isolator 821. In this instance, multiple serially cascaded stages (e.g., 2, 3 or more) of the superconducting switch circuit 820 can be used to reach 60 dB of rejection or more.

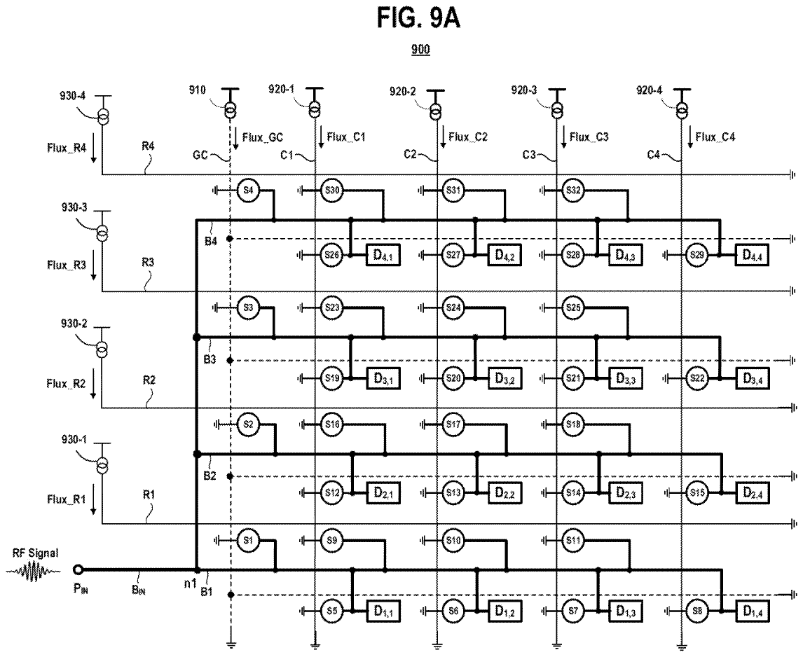

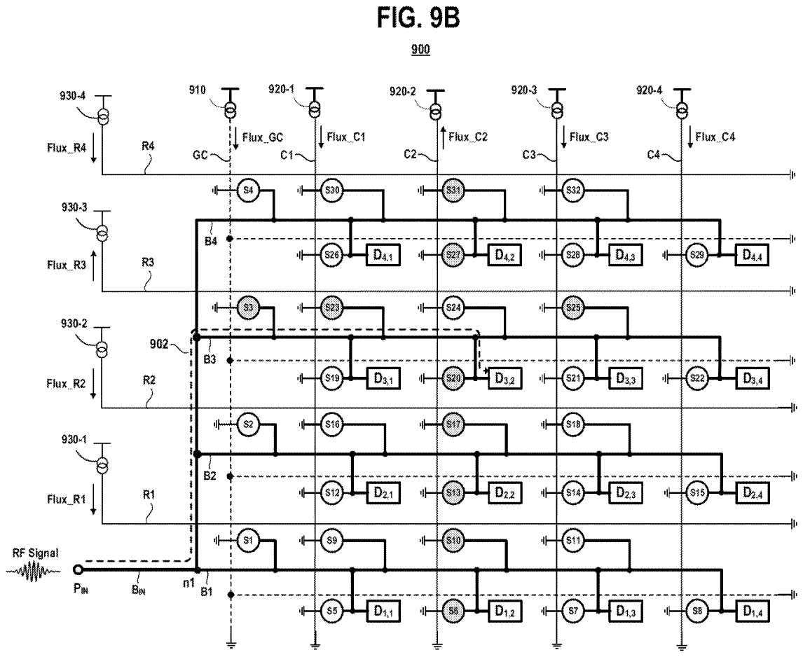

FIG. 9A schematically illustrates a superconducting signal routing circuit, according to an exemplary embodiment of the disclosure. In particular, FIG. 9A schematically illustrates an exemplary embodiment of a superconducting signal routing circuit 900 which comprises a plurality of switch nodes S1, S2, . . . , S32 (alternatively referred to herein as switches), and a plurality of flux bias control lines which comprise (i) a global flux bias control line GC, (ii) a first set of flux bias control lines C1, C2, C3, and C4 (alternatively referred to herein as column control lines) that are arranged to extend in a first (column) direction, and (iii) a second set of flux bias control lines R1, R2, R3, and R4 (alternatively referred to herein as row control lines) that are arranged to extend in a second (row) direction, orthogonal to the first (column) direction. It is to be noted while the global flux bias control line GC is shown as having multiple branches for ease of illustration, in an exemplary embodiment, the global flux bias control line GC is a single continuous control line that is routed through the superconducting signal routing circuit 900 and configured to apply a global flux bias control signal Flux_GC to each of the switch nodes S1-S8, S12-S15, S19-S22, and S26-S29.

The switch nodes S1, S2, . . . , S32 of the superconducting signal routing circuit 900 are controlled by flux bias control signals that are generated by a plurality of flux bias control signal generators 910, 920-1, 920-2, 920-3, 920-4, 930-1, 930-2, 930-3, and 930-4. In particular, as schematically illustrated in FIG. 9A, the flux bias control signal generator 910 is configured to generate the global flux bias control signal Flux_GC. The flux bias control signal generators 920-1, 920-2, 920-3, and 920-4 are configured to generate respective flux bias control signals Flux_C1, Flux_C2, Flux_C3, Flux_C4, which are applied to the respective flux bias (column) control lines C1, C2, C3, and C4. The flux bias control signal generators 930-1, 930-2, 930-3, and 930-4 are configured to generate respective flux bias control signals Flux_R1, Flux_R2, Flux_R3, Flux_R4, which are applied to the respective flux bias (row) control lines R1, R2, R2, and R4. In some embodiments, the flux bias control signals Flux_GC, Flux_R1-Flux_R4, and Flux_C1-Flux_C4 comprise direct current (DC) currents that are applied to the respective flux bias control lines.

The superconducting signal routing circuit 900 comprises a signal input port P_{IN} that is coupled to a common signal input line B_{IN}. The common signal input line B_{IN} is coupled (at node n1) to a plurality of branch signal lines B1, B2, B3, and B4. The input port P_{IN} is configured to receive an RF signal from, e.g., an RF signal generator. The switch nodes S1, S2, . . . , S32 of the superconducting signal routing circuit 900 are arranged in a configuration in which each switch node S1, S2, . . . , S32 is either selectively biased into a low inductance state or a high inductance state at a given time to configure a target signal routing path between the input port P_{IN} and a target quantum device of a plurality of quantum devices (generally denoted, D_{i,j}) that are coupled to the branch signal lines B1, B2, B3, and B4, and thereby route the input RF signal to the target quantum device over the configured signal routing path.

In the exemplary configuration shown in FIG. 9A, the quantum devices D_{i,j} are arranged in an N×N array (e.g., a 4×4 array), and are addressable by a row index i (e.g., i=1, 2, 3, 4) and a column index j (e.g., j=1, 2, 3, 4). For example, the quantum devices D_{1,1}, D_{1,2}, D_{1,3}, and D_{1,4} are coupled to the branch signal line B1, the quantum devices D_{2,1}, D_{2,2}, D_{2,3}, and D_{2,4} are coupled to the branch line B2, the quantum devices D_{3,1}, D_{3,2}, D_{3,3}, and D_{3,4} are coupled to the branch line B3, and the quantum devices D_{4,1}, D_{4,2}, D_{4,3}, and D_{4,4} are coupled to the branch line B4. The quantum devices D_{i,j} may comprise various types of superconducting quantum devices, such as superconducting quantum bits, superconducting amplifiers (e.g., traveling wave parametric amplifiers), etc. In the exemplary configuration shown in FIG. 9A, it is assumed that the input port P_{IN}, the common signal input line B_{N} and branch signal lines B1-B4, and the I/O ports of the quantum devices D_{i,j} have matching nominal characteristic impedances, e.g., Z₀=50Ω.

In an exemplary embodiment, each switch node S1, S2, . . . , S32 comprises at least one DC-SQUID that is coupled to ground to provide an inductive shunt to ground at various points on the branch signal lines B1, B2, B3, and B4. In some embodiments, the switch nodes S1, S2, . . . , S32 are implemented using the exemplary architecture of the switch 110 of FIG. 1, or the exemplary architecture of the switch 210 of FIG. 2. In this regard, for ease of illustration, the switch nodes S1, S2, . . . , S32 are generically depicted in FIG. 9A as circles, although it is to be understood that each of the switch nodes S1, S2, . . . , S32 would include one or more superconducting loops with Josephson junctions, and coupling inductors disposed in adjacent proximity to the superconducting loop(s) thereof. Similar to the exemplary embodiments discussed above, each switch node S1, S2, . . . , S32 can be selectively placed into one of two different states, e.g., a high impedance state or a low impedance state, by controlling a net amount of magnetic flux bias Φ_{bias} that is threaded through the superconducting loop of the switch node. For example, a given switch node will be in a low impedance state (or low inductance state) when a net amount of magnetic flux Φ_{bias}≅0 is threaded through the superconducting loop of the switch node. On the other hand, a given switch node will be in a high impedance state (or high inductance state) when a net amount of magnetic flux Φ_{bias}≅0.5 Φ₀, is threaded through the superconducting loop of the switch node.

In some embodiments, as schematically shown in FIG. 9A, each switch node S1, S2, . . . , S32 is flux-controlled by two (2) flux bias control signals applied on two (2) flux bias control lines that are disposed adjacent to the switch node. For example, the switch nodes S1, S2, S3, and S4 are (i) commonly controlled by the global control line GC, and (ii) independently controlled by the row flux bias control lines R1, R2, R3, and R4, respectively. The switch nodes S5, S6, S7, and S8 are (i) commonly controlled by the global control line GC, and (ii) independently controlled by the column flux bias control lines C1, C2, C3, and C4, respectively. The switch nodes S9, S10, and S11 are (i) commonly controlled by the row flux bias control line R1, and (ii) independently controlled by the column flux bias control lines C1, C2, and C3, respectively. The switch nodes S12, S13, S14, and S15 are (i) commonly controlled by the global control line GC and (ii) independently controlled by the column flux bias control lines C1, C2, C3, and C4, respectively. The switch nodes S16, S17, and S18 are (i) commonly controlled by the row flux bias control line R2, and (ii) independently controlled by the column flux bias control lines C1, C2, and C3, respectively. The switch nodes S19, S20, S21, and S22 are (i) commonly controlled by the global control line GC and (ii) independently controlled by the column flux bias control lines C1, C2, C3, and C4, respectively. The switch nodes S23, S24, and S25 are (i) commonly controlled by the row flux bias control line R3, and (ii) independently controlled by the column flux bias control lines C1, C2, and C3, respectively. The switch nodes S26, S27, S28, and S29 are (i) commonly controlled by the global control line GC, and (ii) independently controlled by the column flux bias control lines C1, C2, C3, and C4, respectively. The switch nodes S30, S31, and S32 are (i) commonly controlled by the row flux bias control line R4, and (ii) independently controlled by the column flux bias control lines C1, C2, and C3, respectively.

Although not specifically shown in FIG. 9A, the global control line GC, the column control lines C1-C4, and the row control lines R1-R4 each comprise a plurality of coupling inductors, where each coupling inductor is disposed in adjacent proximity to a respective switch node, and where each coupling inductor is configured to mutually couple the flux bias control signal on the flux bias control line to the switch node. In other words, when a flux bias control signal (e.g., Flux_R1) is applied to a given flux bias control line (e.g., control line R1), each series coupling inductor on the given flux bias control line will generate a magnetic flux which threads through the superconducting loop of a respective switch node, e.g., each series coupling inductor on the flux bias control line R1 generates a respective magnetic flux which threads through the respective superconducting loop of the respective switch nodes S1, S9, S10, S11.

In some embodiments, the flux bias control signal generator 910 is configured to generate a fixed global flux bias control signal Flux_GC with a fixed polarity. Moreover, the flux bias control signal generators 920-1, 920-2, 920-3, and 920-4 are configured to generate the respective flux bias control signals Flux_C1, Flux_C2, Flux_C3, and Flux_C4, which have a fixed magnitude, and polarities that can be selectively switched between a first polarity (or positive polarity) and a second polarity (or negative polarity). Similarly, the flux bias control signal generators 930-1, 930-2, 930-3, and 930-4 are configured to generate the respective flux bias control signals Flux_R1, Flux_R2, Flux_R3, and Flux_R4, which have a fixed magnitude, and polarities that can be selectively switched between a first polarity (or positive polarity) and a second polarity (or negative polarity).

As noted above, the terms “positive polarity” or “positive current” as used herein denote a current flow in a direction along a flux bias control line from a flux bias control signal generator to a ground node GND, while the terms “negative polarity” or “negative current” as used herein denote a current flow in a direction along a flux bias control line from the ground node GND to a flux bias control signal generator. For example, as schematically illustrated in FIG. 9A, the single-ended arrows next to the flux bias control signal generators 910, 920-1, 920-2, 920-3, 920-4, 930-1, 930-2, 930-3, and 930-4 represent a “positive current” flow on the corresponding flux bias control lines.

In some embodiments, the flux bias control signal generator 910 is configured to generate a fixed global flux bias control signal Flux_GC with a fixed polarity, which is configured to apply a global (fixed) flux bias of, e.g., Φ_{g_bias}=0.25 Φ₀, to each of the switch nodes S1-S8, S12-S15, S19-S22, and S26-S29, as shown in FIG. 9A. On the other hand, the flux bias control signal generators 920-1, 920-2, 920-3, 920-4, 930-1, 930-2, 930-3, 930-4 are configured to generate respective flux bias control signals Flux_C1, Flux_C2, Flux_C3, Flux_C4, Flux_R1, Flux_R2, Flux_R3, and Flux_R4 on the independent flux bias control lines C1, C2, C3, C4, R1, R2, R3, and R4, respectively, to apply a local magnetic flux bias of, e.g., Φ_{bias}=0.25 Φ₀, to the switch nodes. The polarities of the flux bias control signals Flux_C1, Flux_C2, Flux_C3, Flux_C4, Flux_R1, Flux_R2, Flux_R3, and Flux_R4 are selectively configured at a given time to selectively bias different switch nodes S1, S2, . . . , S32 into low or high inductance states, as needed, to configure a RF signal routing path from the input port P_{IN} to a target quantum devices D_{i,j}.

It is to be noted that when each of the flux bias control signals Flux_GC, Flux_C1, Flux_C2, Flux_C3, Flux_C4, Flux_R1, Flux_R2, Flux_R3, and Flux_R4 has a positive polarity (such as shown in FIG. 9A), each switch node S1, S2, . . . , S32 of the superconducting signal routing circuit 900 will be in a low impedance state, such that no signal routing paths are configured in the superconducting signal routing circuit 900, wherein the input port P_{IN} is isolated from all quantum devices D_{i,j}. In this regard, the superconducting signal routing circuit 900 can be configured in a “wait” mode in which each switch node S1, S2, . . . , S32 is biased in a low inductance state with a net amount of magnetic flux bias Φ_{bias}≅0 threaded through the superconducting loops of the switch nodes S1, S2, . . . , S32.

FIG. 9B schematically illustrates an exemplary mode of operation of the superconducting signal routing circuit 900 of FIG. 9A, according to an exemplary embodiment of the disclosure. In particular, FIG. 9B schematically illustrates an exemplary mode of operation of the superconducting signal routing circuit 900 of FIG. 9A for addressing a target quantum device D_{i,j}. In general, the superconducting signal routing circuit 900 is configured to address a target quantum device D_{i,j} (e.g., superconducting qubit) by changing the polarity of a flux bias control signal on a given row control line Ri and a given column control line Cj. For example, FIG. 9B illustrates an exemplary mode of operation for configuring the superconducting signal routing circuit 900 to selectively configurate an RF signal path 902 from the input port P_{IN} to the quantum device D_{3,2} to route in incoming RF signal to the quantum device D_{3,2} via the RF signal path 902.

In FIG. 9B, the switch nodes that are depicted with shaded circles represent switch nodes that are in a high impedance state, while the switch nodes that are depicted with non-shaded circles represent switch nodes that are in a low impedance state. In the exemplary operating state shown in FIG. 9B, the flux bias control signals Flux_GC, Flux_C1, Flux_C3, Flux_C4, Flux_R1, Flux_R2, and Flux_R4 have “positive polarities” while the flux bias control signals Flux_R3 and Flux_C2 are switched to have “negative polarities,” resulting in the respective impedance states of the switch nodes S1-S32, as shown in FIG. 9B. For example, the switch nodes S3, S23, and S20 are each in a high impedance state, thereby allowing transmission of the RF input signal along the RF signal path 902 from the input port P_{IN} to the quantum device D_{3,2}. In addition, the switch nodes S1, S2, and S4 are each in a low impedance state, which essentially blocks the transmission of RF energy on the branch signal lines B1, B2, and B4.

In this regard, it is to be appreciated that the exemplary superconducting signal routing circuit 900 can be selectively configured to route an incoming RF signal to any one of the quantum device D_{i,j} by changing the polarity of one row control line and one column control line having row and column indices (i, j) that correspond to the row and column indices of the targe quantum device D_{i,j}. While the superconducting signal routing circuit 900 illustrates an exemplary N×N array configuration (having N=4) for addressing N²=16 quantum devices D_{i,j}, the superconducting signal routing circuit 900 can be implemented with other values of N (e.g., N=2, 8, 16, etc.). Moreover, in other embodiments, a superconducting signal routing circuit can be configured to address any A×B array of quantum devices, where A≠B.

It is to be noted that the exemplary N×N array configuration as shown in FIG. 9A can be implemented with a total of 2N+2 lines, including N row control lines, N column control lines, one RF signal line, and one global flux control line control line (which is then locally split into the global control branches as discussed above). In a conventional system, N² individual signal lines would be needed to transmit RF control signals to each of the N² quantum devices, while the exemplary superconducting signal routing circuit 900 utilizes one (1) RF signal line to couple an RF signal to any one of N² quantum devices.

In the context of a superconducting quantum computing system with quantum processors and quantum devices disposed in a base stage (e.g., millikelvin stage with temperatures less than 100 millikelvin) of a multi-stage dilution refrigerator, the exemplary superconducting signal routing circuit 900 of FIG. 9A can be disposed in the base stage of the dilution refrigerator. An RF signal line (or high bandwidth control line) is routed from, e.g., room temperature electronics, though the multi-stage dilution refrigerator to the input port P_{IN} of the superconducting signal routing circuit 900, wherein the RF control signal is then routed to one of a plurality of quantum devices disposed in the base stage of the multi-stage dilution refrigerator. Moreover, since the flux bias control lines are superconducting lines disposed in the dilution refrigerator, there is no power dissipation resulting from the flux bias control signals propagating along the flux bias control lines. Therefore, each flux bias control line can be made relatively long to feed a flux bias control signal to a relatively large number of switch nodes (e.g., hundreds of switch nodes) without resulting in degradation of the flux bias control signals due to power dissipation as the flux bias control signals propagate on the flux bias control lines.

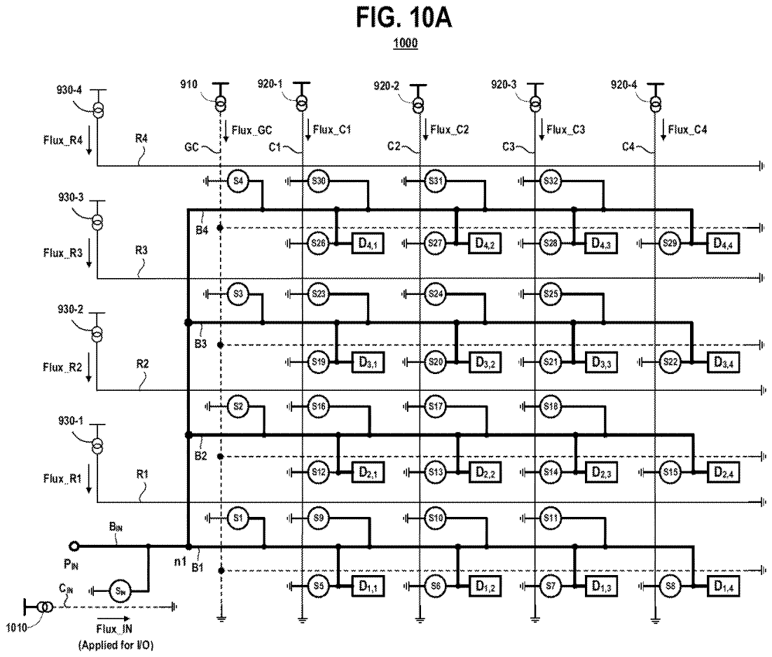

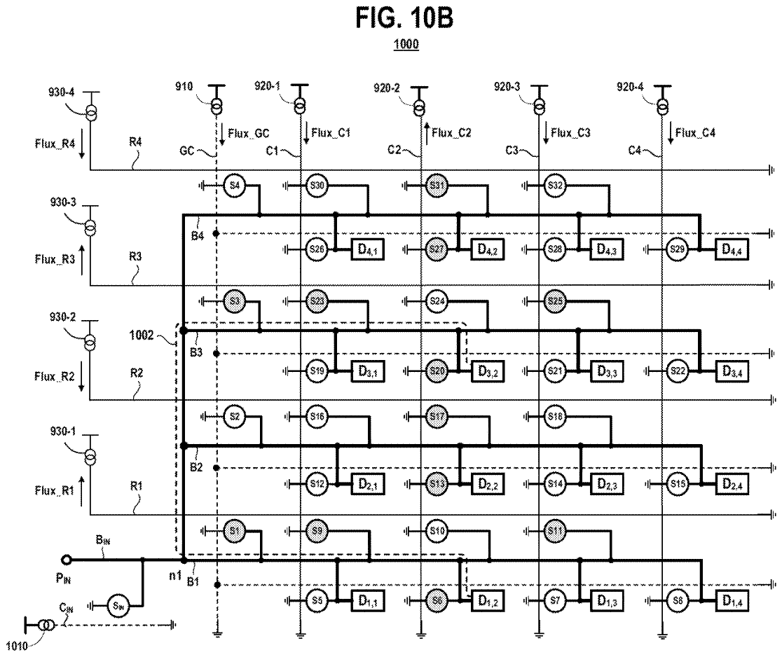

FIG. 10A schematically illustrates a superconducting signal routing circuit, according to another exemplary embodiment of the disclosure. In particular, FIG. 10A schematically illustrates a superconducting signal routing circuit 1000 which has the same architecture as the superconducting signal routing circuit 900 of FIG. 9A, but with an additional flux bias control signal generator 1010, flux bias control line C_{IN}, and input switch node S_{IN}, which are configured to selectively couple or decouple the input port P_{IN} to the input signal line B_{IN}, to enable different modes of operation of the superconducting signal routing circuit 1000.

In particular, the flux bias control signal generator 1010 is configured to generate a flux bias control signal Flux_IN on the flux bias control line C_{IN} to cause the input switch node S_{IN} to be fluxed biased into a high inductance state (e.g., high impedance shunt to ground GND), which essentially results in the dynamic coupling of the input port P_{IN} to the input signal line B_{IN} to thereby allow an RF signal to be routed to a target quantum device D_{i,j}, using the techniques as discussed above. On the other hand, when the input switch node S_{IN} is unbiased (e.g., the flux bias control signal Flux_IN is not applied on flux bias control line C_{IN}) and in the low inductance state, the input switch node S_{IN} provides a low inductive shunt to ground, which breaks the impedance match between the input port P_{IN} and the input signal line B_{IN}. In this regard, biasing the input switch node S_{IN} into the low inductance state essentially results in the dynamic decoupling of the input port P_{IN} and the input signal line B_{IN} to thereby prevent any RF signal I/O at the input port P_{IN}.

In some embodiments, with the inclusion of the flux tunable input switch node S_{IN}, the superconducting signal routing circuit 1000 can be configured to selectively configure a signal routing path between two quantum devices in the array of quantum devices D_{i,j} that are coupled to the superconducting signal routing circuit 1000. For example, FIG. 10B schematically illustrates an exemplary mode of operation of the superconducting signal routing circuit 1000 in which a RF signal routing path 1002 is selectively configured within superconducting signal routing circuit 1000 to couple the quantum devices D_{3,2} and D_{1,2}. In FIG. 10B, the switch nodes that are depicted with shaded circles represent switch nodes that are in a high impedance state, while the switch nodes that are depicted with non-shaded circles represent switch nodes that are in a low impedance state.

In the exemplary operating state shown in FIG. 10B, the flux bias control signals Flux_GC, Flux_C1, Flux_C3, Flux_C4, Flux_R2, and Flux_R4 have “positive polarities” while the flux bias control signals Flux_R1, Flux_R3 and Flux_C2 are switched to have “negative polarities,” resulting in the respective impedance states of the switch nodes S1-S32, as shown in FIG. 10B. For example, the switch nodes S6, S9, S1, S3, S23 and S20 are each in a high impedance state, thereby providing the signal routing path 1002 between the quantum devices D_{3,2} and D_{1,2} that are coupled to the branch signal lines B1 and B3, while the switch nodes S2 and S4 are each in a low impedance state, thereby essentially decoupling the signal line branches B2 and B4 from the signal routing path 1002.

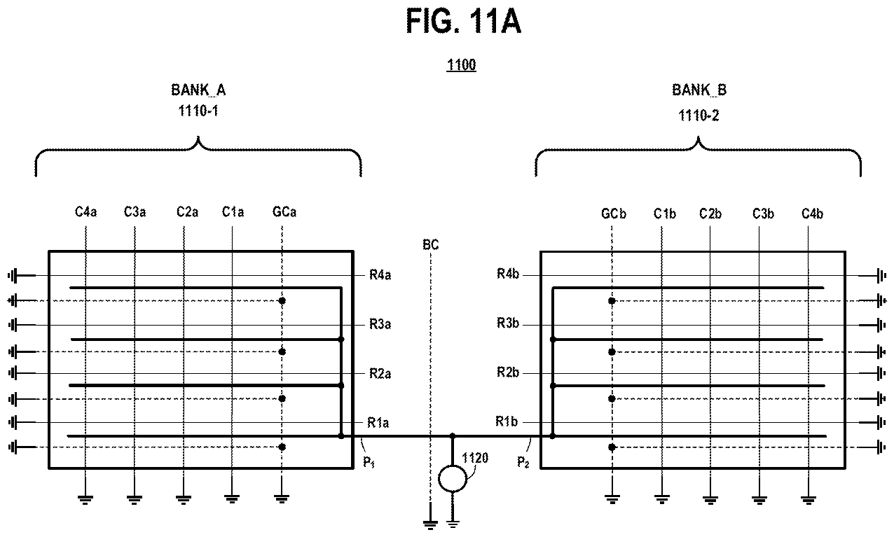

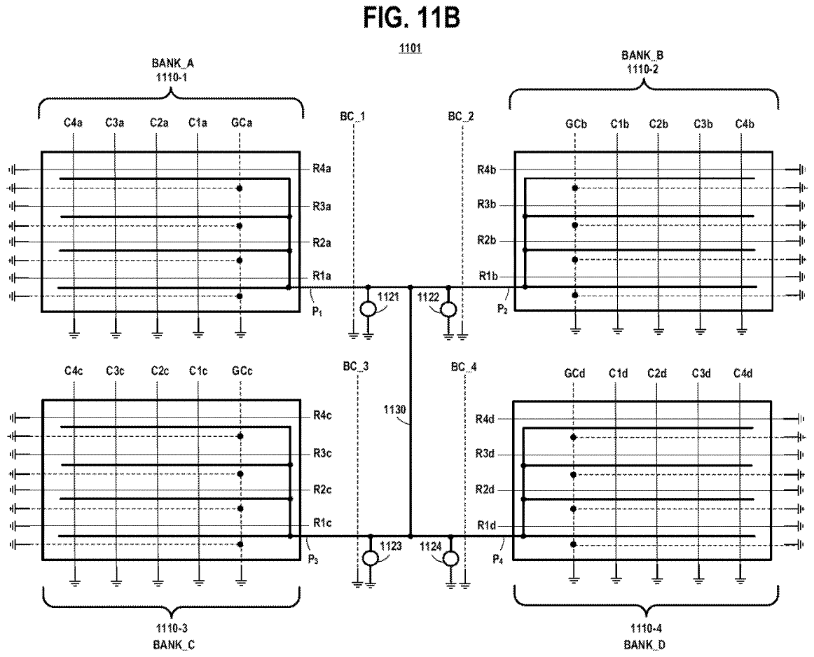

FIG. 11A schematically illustrates a superconducting signal routing circuit, according to another exemplary embodiment of the disclosure. In particular, FIG. 11A schematically illustrates a superconducting signal routing circuit 1100 which comprises a first signal routing circuit 1110-1 that is coupled to a first bank of quantum devices (Bank_A), a second signal routing circuit 1110-2 that is coupled to a second bank of quantum devices (Bank_B), and a switch node 1120 and an associated flux bias control line BC (or bank control line BC). The first signal routing circuit 1110-1 comprises an input/output (I/O) port P₁ coupled to the switch node 1120, and the second signal routing circuit 1110-2 comprises an I/O port P₂ coupled to the switch node 1120. The switch node 1120 is configured to selectively couple or decouple the I/O ports P₁ and P₂ of the first and second signal routing circuits 1110-1 and 1110-2, based on a flux bias control signal applied to the bank control line BC. A bank as illustratively used herein may more generally be referred to as a set.

In some embodiments, the first and second signal routing circuits 1110-1 and 1110-2 comprise the same signal routing circuit architecture as shown in, e.g., FIG. 9A or 10A. The first signal routing circuit 1110-1 comprises a set of flux bias control lines GCa, R1a, R2a, R3a, R4a, C1a, C2a, C3a, and C4a, to selectively generate signal routing paths to quantum devices in the first bank of devices (Bank_A). The second signal routing circuit 1110-2 comprises a set of flux bias control lines GCb, R1b, R2b, R3b, R4b, C1b, C2b, C3b, and C4b, to selectively generate signal routing paths to quantum devices in the second bank of devices (Bank_B).

The switch node 1120 can be placed in a high impedance state by applying a flux bias control signal on the flux bias control line SC to thereby dynamically couple the I/O ports P₁ and P₂ of the first and second signal routing circuits 1110-1 and 1110-2. In this manner, the first and second signal routing circuits 1110-1 and 1110-2 can be configured to establish an RF signal routing path between a quantum device in Bank_A and a quantum device in Bank_B, using the same or similar techniques as discussed above in connection with, e.g., FIG. 9B. On the other hand, the switch node 1120 can be placed in a low impedance state by not applying a flux bias control signal on the flux bias control line SC to thereby dynamically decouple the I/O ports P₁ and P₂ of the first and second signal routing circuits 1110-1 and 1110-2. In this manner, the first and second signal routing circuits 1110-1 and 1110-2 can be operated independently using operating modes such as discussed above in conjunction with, e.g., FIG. 10B.

FIG. 11B schematically illustrates a superconducting signal routing circuit, according to another exemplary embodiment of the disclosure. In particular, FIG. 11B schematically illustrates a superconducting signal routing circuit 1101 which is similar to the superconducting signal routing circuit 1100 of FIG. 11A, except that the superconducting signal routing circuit 1101 comprises a third signal routing circuit 1110-3 that is coupled to a third bank of quantum devices (Bank_C), a fourth signal routing circuit 1110-4 that is coupled to a fourth bank of quantum devices (Bank_D), and a plurality of switch nodes 1121, 1122, 1123, and 1124, and associated flux bias control lines BC_1, BC_2, BC_3, and BC_4 (or bank control lines).

The first signal routing circuit 1110-1 comprises an I/O port P₁ coupled to the switch node 1121. The second signal routing circuit 1110-2 comprises an I/O port P₂ coupled to the switch node 1122. The third signal routing circuit 1110-3 comprises an I/O port P₃ coupled to the switch node 1123. The fourth signal routing circuit 1110-4 comprises an I/O port P₄ coupled to the switch node 1124. The switch nodes 1121, 1122, 1123, and 1124 are coupled via a network of RF signal transmission lines 1130. The switch nodes 1121, 1122, 1123, and 1124 are configured to selectively couple or decouple any combination of the I/O ports P₁, P₂, P₃, and P₄ of the respective signal routing circuits 1110-1, 1110-2, 1110-3, and 1110-4, based on a flux bias control signals that are selectively applied to the bank control lines BC_1, BC_2, BC_3, and BC_4.

In some embodiments, the third and fourth signal routing circuits 1110-3 and 1110-4 comprise the same signal routing circuit architecture as shown in, e.g., FIG. 9A or 10A. The third signal routing circuit 1110-3 comprises a set of flux bias control lines GCc, R1c, R2c, R3c, R4c, C1c, C2c, C3c, and C4c, to selectively generate signal routing paths to quantum devices in the third bank of devices (Bank_C). The fourth signal routing circuit 1110-4 comprises a set of flux bias control lines GCd, R1d, R2d, R3d, R4d, C1d, C2d, C3d, and C4d, to selectively generate signal routing paths to quantum devices in the fourth bank of devices (Bank_D). The superconducting signal routing circuit 1101 comprises various modes of operation similar to the exemplary operating modes of the superconducting signal routing circuit 1100 of FIG. 11A.

For example, the switch nodes 1121, 1122, 1123, and 1124 can each be placed in a low impedance state by not applying flux bias control signals on the respective bank control lines BC_1, BC_2, BC_3, and BC_4 to thereby dynamically decouple the signal routing circuits 1110-1, 1110-2, 1110-3, and 1110-4 from each other. In this manner, the signal routing circuits 1110-1, 1110-2, 1110-3, and 1110-4 can be operated independently using operating modes such as discussed above in conjunction with, e.g., FIG. 10B. On the other hand, any pairwise combination of the signal routing circuits 1110-1, 1110-2, 1110-3, and 1110-4 can be coupled together by placing two of the switch nodes 1121, 1122, 1123, and 1124 in a high impedance state. For example, the switch nodes 1121 and 1123 can be placed in a high impedance state (with the switch nodes 1122 and 1124 maintained in a low impedance state) to thereby couple the I/O ports P₁ and P₃ of the first and third signal routing circuits 1110-1 and 1110-3. In this manner, the first and third signal routing circuits 1110-1 and 1110-3 can be configured to establish an RF signal routing path between a quantum device in Bank_A and a quantum device in Bank_C, using the same or similar techniques as discussed above ion connection with FIG. 9A.

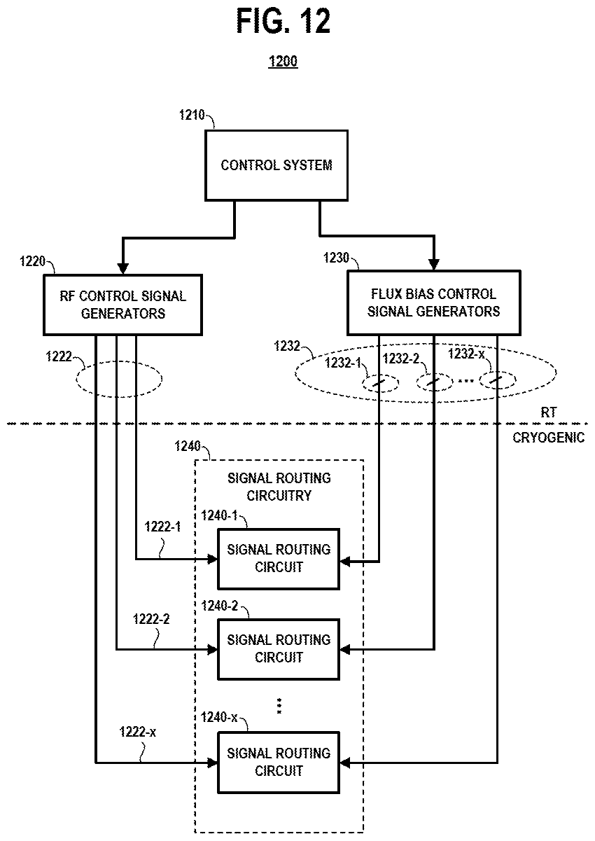

It is to be appreciated that the implementation of superconducting signal routing circuitry as discussed herein, allows multiple quantum devices (e.g., qubits) to be accessed concurrently, using a signal routing control process. For example, FIG. 12 schematically illustrates a quantum computing system 1200 which comprises superconducting signal routing circuitry, according to an exemplary embodiment of the disclosure. The quantum computing system 1200 comprises a control system 1210, RF control signal generators 1220, flux bias control signal generators 1230, and superconducting signal routing circuitry 1240. The superconducting signal routing circuitry 1240 comprises a plurality of signal routing circuits 1240-1, 1240-2, . . . , 1240-x, each comprising superconducting switch nodes that are configured to selectively address a plurality of quantum devices (e.g., superconducting qubits). For example, in some embodiments, the signal routing circuits 1240-1, 1240-2, . . . , 1240-x are each implemented using the exemplary superconducting signal routing circuit 900 of FIG. 9A.

In an exemplary embodiment, the control system 1210, the RF control signal generators 1220, and the flux bias control signal generators 1230 comprise electronic components and systems that are disposed and are operated in a room temperature (RT) environment, while the superconducting signal routing circuitry 1240 and the associated banks of quantum devices (e.g., superconducting qubits) are disposed and operate in a cryogenic temperature environment, e.g., a mK stage of a dilution refrigerator.

The RF control signal generators 1220 are configured to generate RF control signals (e.g., RF control pulses) that are transmitted to the superconducting signal routing circuitry 1240 via a plurality of high-bandwidth RF control lines 1222 from the RT environment to the superconducting signal routing circuitry 1240 in the cryogenic environment. The high-bandwidth RF control lines 1222 comprise individual RF control lines 1222-1, 1222-2, . . . , 1222-x that are coupled to input ports of the respective signal routing circuits 1240-1, 1240-2, . . . , 1240-x. In some embodiments, the RF control signal generators 1220 include, for example, arbitrary waveform generators (AWGs) that are configured to generate different RF control pulses with center frequencies, pulse shapes (e.g., gaussian pulse envelope, etc.), and durations, as needed, to control target quantum devices (e.g., qubits).

The flux bias control signal generators 1230 are configured to generate flux bias control signals (e.g., DC signals, baseband pulses, etc.) that are transmitted to the signal routing circuits 1240-1, 1240-2, . . . , 1240-x via respective sets of flux bias control lines 1232-1, 1232-2, . . . , 1232-x. In some embodiments, flux bias control signal generators 1230 represent the various flux bias control signal generators as shown in FIGS. 9A, 9B, 10A, and 10B, for example.

In some embodiments, the control system 1210 implements a signal routing control process to control and synchronize the operations of the RF control signal generators 1220 and the flux bias control signal generators 1230 to synchronize the generation and output of microwave control signals on the high-bandwidth RF control lines 1222, in conjunction with the selective generation and output of flux bias control signals on the flux bias control lines 1232, to thereby selectively route microwave signals, which are input to the superconducting signal routing circuitry 1240, to target quantum devices that are coupled to the superconducting signal routing circuitry 1240.

In some embodiments, the quantum computing system 1200 is configured to enable multiple superconducting qubits to be addressed concurrently. For example, a quantum processor can have an array of superconducting qubits that is divided into different clusters (e.g., banks or sets) of superconducting qubits which need to be addressed simultaneously. In this regard, the array of superconducting qubits can be divided into x clusters, wherein each cluster of superconducting qubits is coupled to a respective one of the signal routing circuits 1240-1, 1240-2, . . . , 1240-x, wherein the switch nodes of a given superconducting signal routing circuit are controlled (as discussed above) to configure signal routing paths to route signals to and between the superconducting qubits that are included in the cluster of qubits that is coupled to the given superconducting signal routing circuit, as well as selectively configure signal routing paths between superconducting qubits in different qubit clusters.

By way of example, assume a quantum processor comprises 100K superconducting qubits, in which it is desired to simultaneously address clusters of 10 superconducting qubits. In this instance, the 100K superconducting qubits would be divided into 10K clusters (each cluster comprising 10 superconducting qubits). In FIG. 12, the superconducting signal routing circuitry 1240 would have x=10K signal routing circuits, where each signal routing circuit would be coupled to a respective cluster of 10 superconducting qubits. For a processor comprising an array of N² qubits (100K qubits) with clusters of X qubits (clusters of 10 qubits) that need to be addressed simultaneously, the X crossbar matrices would require a total number of lines N²→2NX+2. So, for a processor of 100 k qubits and clusters of 10 qubits to be addressed simultaneously, instead of 100000 lines, the superconducting signal routing circuitry 1240 would need 2002 lines.

While FIG. 12 is discussed in the context of superconducting qubits, as noted above, the superconducting signal routing circuitry 1240 can be coupled to banks of other types of quantum devices. For example, the quantum devices can include superconducting qubit couplers that are responsive to RF control pulses to control exchange interactions between superconducting qubits to facilitate entanglement operations. The quantum devices can be superconducting amplifier devices (e.g., traveling-wave parametric amplifiers) which utilize input RF pump signals for amplifying qubit readout signals. In this instance, the RF control signal generators 1220 can be configured to generate pure tone RF signals to provide pump control signals that are applied to the quantum devices (e.g., traveling-wave parametric amplifiers, or Josephson parametric converters, etc.).

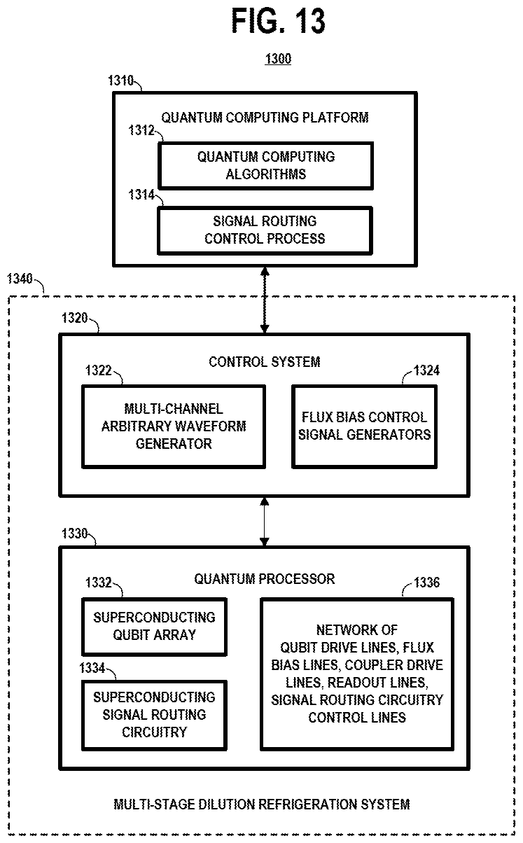

FIG. 13 schematically illustrates a quantum computing system which comprises signal routing circuitry, according to another exemplary embodiment of the disclosure. FIG. 13 schematically illustrates a quantum computing system 1300 which comprises a quantum computing platform 1310, a control system 1320, and a quantum processor 1330. In some embodiments, the quantum computing platform 1310 implements a software platform that is configured to program a quantum computer to execute quantum computing algorithms 1312 which are implemented using, e.g., quantum circuits which define computational routings consisting of coherent quantum operations on quantum data, such as qubits. In addition, in some embodiments, the quantum computing platform 1310 implements software control programs for implementing a signal routing control process 1314 to synchronize the generation of microwave control signals and the routing of the microwave control signals using the superconducting routing circuitry, as discussed herein.

In addition, in some embodiments, the control system 1320 comprises a multi-channel arbitrary waveform generator 1322, and flux bias control signal generators 1324. The quantum processor 1330 comprises one or more solid-state quantum chips which comprise, e.g., a superconducting qubit array 1332, superconducting signal routing circuitry 1334, and a network 1336 of qubit drive lines, coupler flux-bias control lines, qubit state readout lines, and signal routing circuitry control lines, and other circuit QED components that may be needed for a given application or quantum system configuration. The superconducting signal routing circuitry 1334 can be implemented using any of the exemplary embodiments as discussed herein (e.g., FIGS. 9A, 10A, 11A, 11B, and 12).

In some embodiments, the control system 1320 and the quantum processor 1330 are disposed different stages of a dilution refrigeration system 1340 which can generate cryogenic temperatures that are sufficient to operate components of the control system 1320 for quantum computing applications. For example, the quantum processor 1330 may need to be cooled down to near-absolute zero, e.g., 10-15 millikelvin (mK), to allow the superconducting qubits to exhibit quantum behaviors. In some embodiments, the dilution refrigeration system 1340 comprises a multi-stage dilution refrigerator where the components of the control system 1320 can be maintained at different cryogenic temperatures, as needed. For example, while the quantum processor 1330 may need to be cooled down to, e.g., 10-15 mK, the circuit components of the control system 1320 may be operated at cryogenic temperatures greater than 10-15 mK (e.g., cryogenic temperatures in a range of 3K-4K), depending on the configuration of the quantum computing system.

In some embodiments, the superconducting qubit array 1332 comprises a quantum system of superconducting qubits, superconducting qubit couplers, and other components commonly utilized to support quantum processing using qubits. The number of superconducting qubits of the superconducting qubit array 1332 can be on the order of tens, hundreds, thousands, or more, etc. The network 1336 of qubit drive lines, coupler flux bias control lines, and qubit state readout lines, etc., is configured to apply microwave control signals to superconducting qubits and coupler circuitry in the superconducting qubit array 1332 to perform various types of gate operations, e.g., single-gate operations, entanglement gate operations, perform error correction operations, etc., as well as read the quantum states of the superconducting qubits. In some embodiments, the qubit drive lines of the superconducting qubits are coupled to the signal routing circuitry 1334, wherein the signal routing circuitry 1334 is configured to receive microwave control signals from the multi-channel arbitrary waveform generator 1322 and selectively route the microwave control signals to target qubits, in response to flux bias control signals applied by the flux bias control signal generators 1324. For example, microwave control pulses can be selectively applied to the qubit drive lines of respective superconducting qubits to change the quantum state of the superconducting qubits (e.g., change the quantum state of a given qubit between the ground state and excited state, or to a superposition state) when executing quantum information processing algorithms.

The network 1336 of qubit drive lines, coupler flux bias control lines, qubit state readout lines, and signal routing circuitry control lines, etc., is coupled to the control system 1320 through a suitable hardware input/output (I/O) interface, which couples I/O signals between the control system 1320 and the quantum processor 1330. For example, the hardware I/O interface may comprise various types of hardware and components, such as RF cables, wiring, RF elements, optical fibers, heat exchanges, filters, amplifiers, isolators, etc.

In some embodiments, the multi-channel AWG 1322 and other suitable microwave pulse signal generators are configured to generate the microwave control pulses that are applied to the qubit drive lines, and the coupler drive lines to control the operation of the superconducting qubits and associated qubit coupler circuitry, when performing various gate operations to execute a given certain quantum information processing algorithm. In some embodiments, the multi-channel AWG 1322 comprises a plurality of AWG channels, which control respective superconducting qubits within the superconducting qubit array 1332 of the quantum processor 1330. In some embodiments, each AWG channel comprises a baseband signal generator, a digital-to-analog converter (DAC) stage, a filter stage, a modulation stage, an impedance matching network, and a phase-locked loop system to generate local oscillator (LO) signals (e.g., quadrature LO signals LO_I and LO_Q) for the respective modulation stages of the respective AWG channels.

In some embodiments, the multi-channel AWG 1322 comprises a quadrature AWG system which is configured to process quadrature signals, wherein a quadrature signal comprises an in-phase (I) signal component, and a quadrature-phase (Q) signal component. In each AWG channel the baseband signal generator is configured to receive baseband data as input (e.g., from the quantum computing platform), and generate digital quadrature signals I and Q which represent the input baseband data. In this process, the baseband data that is input to the baseband signal generator for a given AWG channel is separated into two orthogonal digital components including an in-phase (I) baseband component and a quadrature-phase (Q) baseband component. The baseband signal generator for the given AWG channel will generate the requisite digital quadrature baseband IQ signals which are needed to generate an analog waveform (e.g., sinusoidal voltage waveform) with a target center frequency that is configured to operate or otherwise control a given quantum bit that is coupled to the output of the given AWG channel.

The DAC stage for the given AWG channel is configured to convert a digital baseband signal (e.g., a digital IQ signal output from the baseband signal generator) to an analog baseband signal (e.g., analog baseband signals I(t) and Q(t)) having a baseband frequency. The filter stage for the given AWG channel is configured to filter the IQ analog signal components output from the DAC stage to thereby generate filtered analog IQ signals. The modulation stage for the given AWG channel is configured to perform analog IQ signal modulation (e.g., single-sideband (SSB) modulation) by mixing the filtered analog signals I(t) and Q(t), which are output from the filter stage, with quadrature LO signals (e.g., an in-phase LO signal (LO_I) and a quadrature-phase LO signal (LO_Q)) to generate and output an analog RF signal (e.g., a single-sideband modulated RF output signal).

The quantum computing platform 1310 comprises a software and hardware platform which comprises various software layers that are configured to perform various functions, including, but not limited to, generating and implementing various quantum applications using suitable quantum programming languages, configuring and implementing various quantum gate operations, compiling quantum programs into a quantum assembly language, implementing and utilizing a suitable quantum instruction set architecture (ISA), performing calibration operations to calibrate the quantum circuit elements and gate operations, etc. In addition, the quantum computing platform 1310 comprises a hardware architecture of processors, memory, etc., which is configured to control the execution of quantum applications, and interface with the control system 1320 to (i) generate digital control signals that are converted to analog microwave control signals by the control system 1320, to control operations of the quantum processor 1330 when executing a given quantum application, and (ii) to obtain and process digital signals received from the control system 1320, which represent the processing results generated by the quantum processor 1330 when executing various gate operations for a given quantum application.

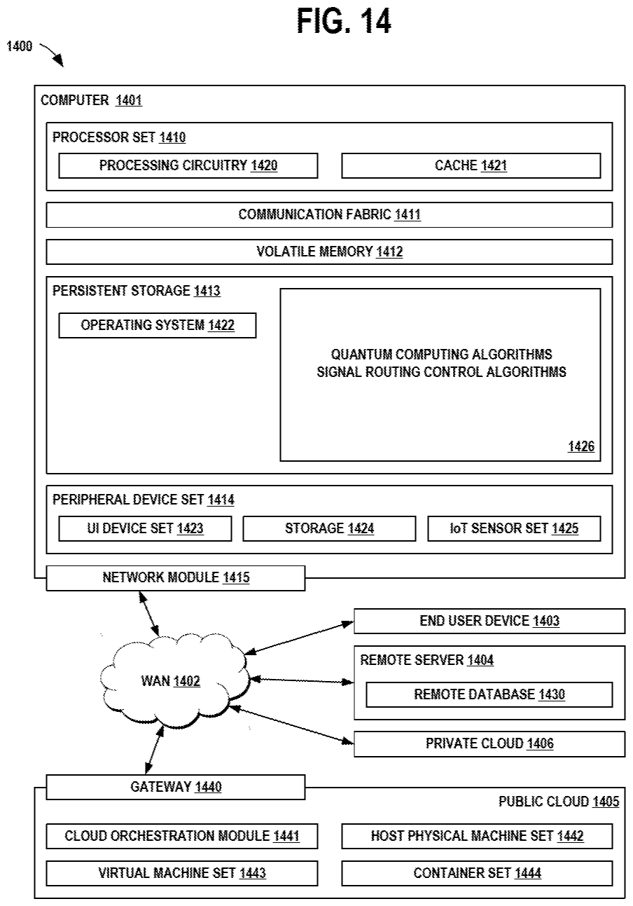

In some exemplary embodiments, the quantum computing platform 1310 of the quantum computing system 1300 may be implemented using any suitable computing system architecture (e.g., as shown in FIG. 14) which is configured to implement methods to support quantum computing operations by executing computer readable program instructions that are embodied on a computer program product which includes a computer readable storage medium (or media) having such computer readable program instructions thereon for causing a processor to perform control methods as discussed herein.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 1400 of FIG. 14 contains an example of an environment for the execution of at least some of the computer code (block 1426) involved in executing quantum computing algorithms (e.g., quantum computing algorithms, and signal routing control processes). In addition to block 1426, computing environment 1400 includes, for example, computer 1401, wide area network (WAN) 1402, end user device (EUD) 1403, remote server 1404, public cloud 1405, and private cloud 1406. In this embodiment, computer 1401 includes processor set 1410 (including processing circuitry 1420 and cache 1421), communication fabric 1411, volatile memory 1412, persistent storage 1413 (including operating system 1422 and block 1426, as identified above), peripheral device set 1414 (including user interface (UI), device set 1423, storage 1424, and Internet of Things (IoT) sensor set 1425), and network module 1415. Remote server 1404 includes remote database 1430. Public cloud 1405 includes gateway 1440, cloud orchestration module 1441, host physical machine set 1442, virtual machine set 1443, and container set 1444.

Computer 1401 may take the form of a desktop computer, laptop computer, tablet computer, smart phone, smart watch or other wearable computer, mainframe computer, quantum computer or any other form of computer or mobile device now known or to be developed in the future that is capable of running a program, accessing a network or querying a database, such as remote database 1430. As is well understood in the art of computer technology, and depending upon the technology, performance of a computer-implemented method may be distributed among multiple computers and/or between multiple locations. On the other hand, in this presentation of computing environment 1400, detailed discussion is focused on a single computer, specifically computer 1401, to keep the presentation as simple as possible. Computer 1401 may be located in a cloud, even though it is not shown in a cloud in FIG. 14. On the other hand, computer 1401 is not required to be in a cloud except to any extent as may be affirmatively indicated.

Processor set 1410 includes one, or more, computer processors of any type now known or to be developed in the future. Processing circuitry 1420 may be distributed over multiple packages, for example, multiple, coordinated integrated circuit chips. Processing circuitry 1420 may implement multiple processor threads and/or multiple processor cores. Cache 1421 is memory that is located in the processor chip package(s) and is typically used for data or code that should be available for rapid access by the threads or cores running on processor set 1410. Cache memories are typically organized into multiple levels depending upon relative proximity to the processing circuitry. Alternatively, some, or all, of the cache for the processor set may be located “off chip.” In some computing environments, processor set 1410 may be designed for working with qubits and performing quantum computing.

Computer readable program instructions are typically loaded onto computer 1401 to cause a series of operational steps to be performed by processor set 1410 of computer 1401 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1421 and the other storage media discussed below. The program instructions, and associated data, are accessed by processor set 1410 to control and direct performance of the inventive methods. In computing environment 1400, at least some of the instructions for performing the inventive methods may be stored in block 1426 in persistent storage 1413.

Communication fabric 1411 is the signal conduction paths that allow the various components of computer 1401 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 1412 is any type of volatile memory now known or to be developed in the future. Examples include dynamic type random access memory (RAM) or static type RAM. Typically, the volatile memory is characterized by random access, but this is not required unless affirmatively indicated. In computer 1401, the volatile memory 1412 is located in a single package and is internal to computer 1401, but, alternatively or additionally, the volatile memory may be distributed over multiple packages and/or located externally with respect to computer 1401.

Persistent storage 1413 is any form of non-volatile storage for computers that is now known or to be developed in the future. The non-volatility of this storage means that the stored data is maintained regardless of whether power is being supplied to computer 1401 and/or directly to persistent storage 1413. Persistent storage 1413 may be a read only memory (ROM), but typically at least a portion of the persistent storage allows writing of data, deletion of data and re-writing of data. Some familiar forms of persistent storage include magnetic disks and solid-state storage devices. Operating system 1422 may take several forms, such as various known proprietary operating systems or open source Portable Operating System Interface type operating systems that employ a kernel. The code included in block 1426 typically includes at least some of the computer code involved in performing the inventive methods.

Peripheral device set 1414 includes the set of peripheral devices of computer 1401. Data communication connections between the peripheral devices and the other components of computer 1401 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1423 may include components such as a display screen, speaker, microphone, wearable devices (such as goggles and smart watches), keyboard, mouse, printer, touchpad, game controllers, and haptic devices. Storage 1424 is external storage, such as an external hard drive, or insertable storage, such as an SD card. Storage 1424 may be persistent and/or volatile. In some embodiments, storage 1424 may take the form of a quantum computing storage device for storing data in the form of qubits. In embodiments where computer 1401 is required to have a large amount of storage (for example, where computer 1401 locally stores and manages a large database) then this storage may be provided by peripheral storage devices designed for storing very large amounts of data, such as a storage area network (SAN) that is shared by multiple, geographically distributed computers. IoT sensor set 1425 is made up of sensors that can be used in Internet of Things applications. For example, one sensor may be a thermometer and another sensor may be a motion detector.

Network module 1415 is the collection of computer software, hardware, and firmware that allows computer 1401 to communicate with other computers through WAN 1402. Network module 1415 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1415 are performed on the same physical hardware device. In other embodiments (for example, embodiments that utilize software-defined networking (SDN)), the control functions and the forwarding functions of network module 1415 are performed on physically separate devices, such that the control functions manage several different network hardware devices. Computer readable program instructions for performing the inventive methods can typically be downloaded to computer 1401 from an external computer or external storage device through a network adapter card or network interface included in network module 1415.

WAN 1402 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

End user device (EUD) 1403 is any computer system that is used and controlled by an end user (for example, a customer of an enterprise that operates computer 1401), and may take any of the forms discussed above in connection with computer 1401. EUD 1403 typically receives helpful and useful data from the operations of computer 1401. For example, in a hypothetical case where computer 1401 is designed to provide a recommendation to an end user, this recommendation would typically be communicated from network module 1415 of computer 1401 through WAN 1402 to EUD 1403. In this way, EUD 1403 can display, or otherwise present, the recommendation to an end user. In some embodiments, EUD 1403 may be a client device, such as thin client, heavy client, mainframe computer, desktop computer and so on.

Remote server 1404 is any computer system that serves at least some data and/or functionality to computer 1401. Remote server 1404 may be controlled and used by the same entity that operates computer 1401. Remote server 1404 represents the machine(s) that collect and store helpful and useful data for use by other computers, such as computer 1401. For example, in a hypothetical case where computer 1401 is designed and programmed to provide a recommendation based on historical data, then this historical data may be provided to computer 1401 from remote database 1430 of remote server 1404.

Public cloud 1405 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 1405 is performed by the computer hardware and/or software of cloud orchestration module 1441. The computing resources provided by public cloud 1405 are typically implemented by virtual computing environments that run on various computers making up the computers of host physical machine set 1442, which is the universe of physical computers in and/or available to public cloud 1405. The virtual computing environments (VCEs) typically take the form of virtual machines from virtual machine set 1443 and/or containers from container set 1444. It is understood that these VCEs may be stored as images and may be transferred among and between the various physical machine hosts, either as images or after instantiation of the VCE. Cloud orchestration module 1441 manages the transfer and storage of images, deploys new instantiations of VCEs and manages active instantiations of VCE deployments. Gateway 1440 is the collection of computer software, hardware, and firmware that allows public cloud 1405 to communicate through WAN 1402.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 1406 is similar to public cloud 1405, except that the computing resources are only available for use by a single enterprise. While private cloud 1406 is depicted as being in communication with WAN 1402, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1405 and private cloud 1406 are both part of a larger hybrid cloud.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, and to enable others of ordinary skill in the art to understand the embodiments disclosed herein.

What is claimed is:

1. A device, comprising:
a superconducting switch which comprises at least one impedance tunable element coupled to and between a transmission line and a ground node, the transmission line coupling a first port and a second port which have matched impedances, the at least one impedance tunable element comprising a superconducting loop comprising at least one Josephson junction, which is configured to be flux tuned into one of a first impedance state and a second impedance state;
wherein in the first impedance state, the at least one impedance tunable element shunts the transmission line to the ground node with an impedance that disrupts the impedance match between the first port and the second port to suppress signal transmission between the first port and the second port over the transmission line; and
wherein in the second impedance state, the at least one impedance tunable element shunts the transmission line to the ground node with an impedance that maintains the impedance match between the first port and the second port to allow signal transmission between the first port and the second ports over the transmission line.

2. The device of claim 1, wherein the at least one impedance tunable element comprises a flux tunable inductance.

3. The device of claim 1, wherein the at least one impedance tunable element comprises at least one direct current superconducting quantum interference device.

4. The device of claim 1, wherein the at least one impedance tunable element comprises at least two direct current superconducting quantum interference devices which are connected in parallel between the transmission line and the ground node.

5. The device of claim 1, further comprising a control line coupled to the superconducting switch, wherein assertion of a control signal on control line causes a magnetic flux to be generated and threaded through the superconducting loop of the at least one impedance tunable element to flux bias the at least one impedance tunable element into the second impedance state, and wherein de-assertion of the control signal on the control line causes the at least one impedance tunable element to be unbiased and placed into the first impedance state.

6. The device of claim 5, wherein the control signal comprises a current pulse having a pulse shape that is imparted to a microwave signal that is transmitted on the transmission line to generate an amplitude modulated microwave signal having a signal envelope which corresponds to the pulse shape of the current pulse.

7. The device of claim 1, further comprising:
a first control line and a second control line coupled to the superconducting switch;
wherein the first control line is configured to apply a first control signal with a first polarity to the superconducting switch to cause a first magnetic flux to be generated and threaded through the superconducting loop of the at least one impedance tunable element;
wherein the second control line is configured to apply a second control signal with a second polarity to the superconducting switch to cause a second magnetic flux to be generated and threaded through the superconducting loop of the at least one impedance tunable element;
wherein the at least one impedance tunable element is flux tuned into the first impedance state, when the first and second polarities of the first and second control signals cause the first magnetic flux and the second magnetic flux to thread though the superconducting loop in opposite directions; and
wherein the at least one impedance tunable element is flux tuned into the second impedance state, when the first and second polarities of the first and second control signals cause the first magnetic flux and the second magnetic flux to thread though the superconducting loop in a same direction.

8. The device of claim 1, wherein the transmission line, the first port, and the second port have matched nominal characteristic impedances.

9. The device of claim 1, further comprising:
a quantum processor comprising a plurality of superconducting quantum bits;
wherein the transmission line is coupled to at least one quantum bit of the quantum processor;
wherein the superconducting switch is configured to isolate the at least one quantum bit from the transmission line when the at least one impedance tunable element is in the first impedance state.

10. A device, comprising:
a superconducting switch circuit comprising: switch nodes; control lines; an input port and a plurality of output ports, which have matched impedances; and a plurality of signal transmission paths, wherein each signal transmission path couples the input port to a respective one of the output ports;
wherein the control lines are configured to apply flux bias control signals to the switch nodes to selectively enable any one of the signal transmission paths to couple the input port to any one of the output ports, in response to the flux bias control signals applied to the switch nodes; and
wherein each switch node comprises at least one impedance tunable element coupled to and between a given signal transmission path and a ground node, the at least one impedance tunable element comprising a superconducting loop comprising at least one Josephson junction, which is configured to be flux tuned into one of a first impedance state and a second impedance state;
wherein in the first impedance state, the at least one impedance tunable element shunts the given signal transmission path to the ground node with an impedance that disrupts the impedance match between the input port and a given output port coupled to the given signal transmission path to suppress signal transmission on the given signal transmission path; and
wherein in the second impedance state, the at least one impedance tunable element shunts the signal transmission path to the ground node with an impedance that maintains the impedance match between the input port and the given output port coupled to the given signal transmission path to allow signal transmission on the given signal transmission path.

11. The device of claim 10, wherein the at least one impedance tunable element comprises a flux tunable inductance.

12. The device of claim 10, wherein the at least one impedance tunable element comprises at least one direct current superconducting quantum interference device.

13. The device of claim 10, wherein the at least one impedance tunable element comprises at least two direct current superconducting quantum interference devices which are connected in parallel.

14. The device of claim 10, wherein:
the control lines comprise a global control line and local control lines;
each switch node is coupled to the global control line and one of the local control lines;
the global control line is configured to apply a first control signal with a first polarity to each switch node to cause a first magnetic flux to be generated and threaded through the superconducting loop of the at least one impedance tunable element of each switch node;
a given local control line coupled to a given switch node is configured to apply a second control signal with a second polarity to the given switch node cause a second magnetic flux to be generated and threaded through the superconducting loop of the at least one impedance tunable element of the given switch node;
wherein the at least one impedance tunable element of the given switch node is flux tuned into the first impedance state, when the first and second polarities of the first and second control signals cause the first magnetic flux and the second magnetic flux to thread though the superconducting loop in opposite directions; and
wherein the at least one impedance tunable element of the given switch node is flux tuned into the second impedance state, when the first and second polarities of the first and second control signals cause the first magnetic flux and the second magnetic flux to thread though the superconducting loop in a same direction.

15. The device of claim 10, wherein:
the signal transmission paths comprise transmission lines; and
the input port, the output ports, and the transmission lines have matched nominal characteristic impedances.

16. A system, comprising:
a quantum processor comprising superconducting quantum bits;
a superconducting signal routing circuit coupled to the quantum processor; and
a control system which is coupled to the superconducting signal routing circuit by control lines, and configured to control operation of the superconducting signal routing circuit;
wherein the superconducting signal routing circuit comprises: switch nodes; an input port and a plurality of output ports, which have matched impedances; and a plurality of signal transmission paths, wherein each signal transmission path couples the input port to a respective one of the output ports, each output port being coupled to a respective one of the superconducting quantum bits;
wherein the control lines of the control system are configured to apply flux bias control signals to the switch nodes to selectively enable any one of the signal transmission paths to couple the input port to any one of the output ports, in response to the flux bias control signals applied to the switch nodes;
wherein each switch node comprises at least one impedance tunable element coupled to and between a given signal transmission path and a ground node, the at least one impedance tunable element comprising a superconducting loop comprising at least one Josephson junction, which is configured to be flux tuned into one of a first impedance state and a second impedance state;
wherein in the first impedance state, the at least one impedance tunable element shunts the given signal transmission path to the ground node with an impedance that disrupts the impedance match between the input port and a given output port coupled to the given signal transmission path to suppress signal transmission on the given signal transmission path; and
wherein in the second impedance state, the at least one impedance tunable element shunts the signal transmission path to the ground node with an impedance that maintains the impedance match between the input port and the given output port coupled to the given signal transmission path to allow signal transmission on the given signal transmission path.

17. The system of claim 16, wherein:
the switch nodes of the superconducting signal routing circuit are arranged in an array;
the control lines comprise first control lines that are disposed in a first direction of the array, and second control lines that are disposed in a second direction of the array, different from the first direction; and
each switch node is flux controlled by one of the first control lines and one of the second control lines.

18. The system of claim 17, wherein each superconducting quantum bit coupled to an output port of the superconducting signal routing circuit is addressable by a first index corresponding to an index of one of the first control lines, and a second index corresponding to an index of one of the second control lines.

19. The system of claim 17, wherein the control lines comprise at least one global control line that applies a flux control signal with a constant magnitude and polarity to at least some of the switch nodes.

20. The system of claim 16, wherein the switch nodes are arranged to selectively configure a signal transmission path between two superconducting quantum bits coupled to different output ports of the superconducting signal routing circuit, in response to flux bias control signals applied to the switch nodes.
